(19) United States
(12) Patent Application Publication
(10) Pub. No.: US 2015/0329371 A1
(43) Pub. Date: Nov. 19, 2015

(54) OXIDE, SEMICONDUCTOR DEVICE, MODULE, AND ELECTRONIC DEVICE

(71) Applicant: Semiconductor Energy Laboratory Co., Ltd., Atsugi-shi (JP)

(72) Inventors: Yoichi KUROSAWA, Atsugi (JP); Masashi OOTA, Atsugi (JP); Shunpei YAMAZAKI, Tokyo (JP)

(21) Appl. No.: 14/661,595

(22) Filed: Mar. 18, 2015

(30) Foreign Application Priority Data
May 13, 2014 (JP) 2014-099578
Jun. 19, 2014 (JP) 2014-126080
Oct. 7, 2014 (JP) 2014-206219

(51) Int. Cl. C01G 19/00; C01G 15/00; H05K 1/18; H01L 29/24; H01L 29/786

(52) U.S. Cl. CPC C01G 19/006; H01L 29/24; H01L 29/7869; H01L 29/78648; H05K 1/182; C01G 15/006; H05K 2201/10037; H05K 2201/10083

(57) ABSTRACT

The oxide includes indium, an element M, and zinc. The oxide includes a first region and a second region. A peak of diffraction intensity derived from a crystal structure is not observed in the first region using X-ray. An electron diffraction pattern including a third region with high luminance in a ring pattern and a spot in the third region is observed by transmission of an electron beam having a probe diameter of 0.3 nm or more and 3 nm or less through the second region. The oxide includes a crystal part when being observed with a transmission electron microscope.

### BACKGROUND OF THE INVENTION

1. Field of the Invention

The present invention relates to, for example, an oxide, a transistor, a semiconductor device, and a manufacturing method thereof. Furthermore, the present invention relates to, for example, an oxide, a display device, a light-emitting device, a lighting device, a power storage device, a memory device, a processor, and an electronic device. Furthermore, the present invention relates to a method for manufacturing an oxide, a display device, a liquid crystal display device, a light-emitting device, a memory device, or an electronic device. Furthermore, the present invention relates to a driving method of a semiconductor device, a display device, a liquid crystal display device, a light-emitting device, a memory device, or an electronic device.

Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter.

In this specification and the like, a semiconductor device generally means a device that can function by utilizing semiconductor characteristics. A display device, a light-emitting device, a lighting device, an electro-optical device, a semiconductor circuit, and an electronic device include a semiconductor device in some cases.

2. Description of the Related Art

A technique for forming a transistor by using a semiconductor over a substrate having an insulating surface has attracted attention. The transistor is applied to a wide range of semiconductor devices such as an integrated circuit and a display device. Silicon is known as a semiconductor applicable to a transistor.

As silicon which is used as a semiconductor of a transistor, either amorphous silicon or polycrystalline silicon is used depending on the purpose. For example, in the case of a transistor included in a large display device, it is preferable to use amorphous silicon, which can be used to form a film on a large substrate with the established technique. On the other hand, in the case of a transistor included in a high-performance display device where a driver circuit and a pixel circuit are formed over the same substrate, it is preferable to use polycrystalline silicon, which can be used to form a transistor having a high field-effect mobility. As a method for forming polycrystalline silicon, high-temperature heat treatment or laser light treatment which is performed on amorphous silicon has been known.

Recently, a transistor which includes an amorphous oxide semiconductor and a transistor which includes an amorphous oxide semiconductor containing a microcrystal have been disclosed (see Patent Document 1). An oxide semiconductor can be formed by a sputtering method or the like, and thus can be used for a semiconductor of a transistor in a large display device. Furthermore, a transistor including an oxide semiconductor has a high field-effect mobility; therefore, a high-performance display device where a driver circuit and a pixel circuit are formed over the same substrate can be obtained. In addition, there is an advantage that capital investment can be reduced because part of production equipment for a transistor including amorphous silicon can be retrofitted and utilized.

In 1985, synthesis of an In—Ga—Zn oxide crystal was reported (see Non-Patent Document 1). Further, in 1995, it was reported that an In—Ga—Zn oxide has a homologous structure and is represented by a composition formula InGaO₃(ZnO)ₘ (m is a natural number) (see Non-Patent Document 2).

In 2014, it was reported that a transistor including a crystalline In—Ga—Zn oxide has more excellent electrical characteristics and higher reliability than a transistor including an amorphous In—Ga—Zn oxide film (see Non-Patent Document 3). Non-Patent Document 3 reports that a crystal boundary is not clearly observed in an In—Ga—Zn oxide including a c-axis aligned crystalline oxide semiconductor (CAAC-OS).

It is known that a transistor including an oxide semiconductor has an extremely low leakage current in an off state. For example, a CPU or the like with low-power consumption utilizing a characteristic of low leakage current of a transistor including an oxide semiconductor is disclosed (see Patent Document 2). Patent Document 3 discloses that a transistor having high field-effect mobility can be obtained by a well potential formed using an active layer formed of an oxide semiconductor.

### REFERENCES

### Patent Documents

[Patent Document 1] Japanese Published Patent Application No. 2006-165528
[Patent Document 2] Japanese Published Patent Application No. 2012-257187
[Patent Document 3] Japanese Published Patent Application No. 2012-59860

### Non-Patent Documents

[Non-Patent Document 1] N. Kimizuka, and T. Mohri, Journal of Solid State Chemistry, Vol. 60, 1985, pp. 382-384
[Non-Patent Document 2] N. Kimizuka, M. Isobe, and M. Nakamura, Journal of Solid State Chemistry, Vol. 116, 1995, pp. 170-178
[Non-Patent Document 3] S. Yamazaki, H. Suzawa, K. Inoue, K. Kato, T. Hirohashi, K. Okazaki, and N. Kimizuka, Japanese Journal of Applied Physics, Vol. 53, 2014, 04ED18

### SUMMARY OF THE INVENTION

An object of the present invention is to provide an oxide that can be used as a semiconductor of a transistor or the like. In particular, an object is to provide a homogeneous oxide.

Another object is to provide a semiconductor device using an oxide as a semiconductor. Another object is to provide a module that includes a semiconductor device using an oxide as a semiconductor. Another object is to provide an electronic device including a semiconductor device using an oxide as a semiconductor or a module including a semiconductor device using an oxide as a semiconductor.

Another object is to provide a transistor with favorable electrical characteristics. Another object is to provide a transistor having stable electrical characteristics. Another object is to provide a transistor with high frequency characteristics. Another object is to provide a transistor having low off-state current. Another object is to provide a semiconductor device including the transistor. Another object is to provide a module including the semiconductor device. Another object is to provide an electronic device including the semiconductor device or the module. Another object is to provide a novel semiconductor device. Another object is to provide a novel module. Another object is to provide a novel electronic device.

Note that the descriptions of these objects do not disturb the existence of other objects. In one embodiment of the present invention, there is no need to achieve all the objects. Other objects will be apparent from and can be derived from the description of the specification, the drawings, the claims, and the like.

(1)

One embodiment of the present invention is an oxide including indium, an element M (the element M is aluminum, gallium, yttrium, or tin), and zinc. The oxide includes a first region, and, in the first region, a peak of diffraction intensity derived from a crystal structure is not observed using X-ray. The oxide includes a second region, and an electron diffraction pattern including a third region with high luminance in a ring pattern and a spot in the third region is observed by transmission of an electron beam having a probe diameter of 0.3 nm or more and 3 nm or less through the second region. The oxide includes a crystal part when being observed with a transmission electron microscope. The crystal part has a first length in a longitudinal direction, and change in the first length is less than 10% when the oxide is subjected to electron irradiation and the total amount of the electron irradiation is 1×10⁸ e⁻/nm² or more and 4×10⁸ e⁻/nm² or less.

(2)

Another embodiment of the present invention is a semiconductor device including a semiconductor including the oxide described in (1), an insulator, and a conductor. The insulator includes a region in contact with the semiconductor, and the conductor includes a region where the conductor and the semiconductor overlap with each other with the insulator provided therebetween.

(3)

Another embodiment of the present invention is a module including the semiconductor device described in (2) and a printed board.

(4)

Another embodiment of the present invention is an electronic device including the semiconductor device described in (2) or the module described in (3), a speaker, an operation key, or a battery.

It is possible to provide an oxide that can be used as a semiconductor of a transistor or the like. In particular, it is possible to provide a method for forming an oxide with fewer defects such as grain boundaries.

It is possible to provide a semiconductor device using an oxide as a semiconductor. It is possible to provide a module that includes a semiconductor device using an oxide as a semiconductor. It is possible to provide a semiconductor device using an oxide as a semiconductor or an electronic device including a module including a semiconductor device using an oxide as a semiconductor.

A transistor with favorable electrical characteristics can be provided. A transistor having stable electrical characteristics can be provided. A transistor with high frequency characteristics can be provided. A transistor having low off-state current can be provided. A semiconductor device including the transistor can be provided. A module including the semiconductor device can be provided. An electronic device including the semiconductor device or the module can be provided. A novel semiconductor device can be provided. A novel module can be provided. A novel electronic device can be provided.

Note that the description of these effects does not disturb the existence of other effects. One embodiment of the present invention does not necessarily achieve all the effects listed above. Other effects will be apparent from and can be derived from the description of the specification, the drawings, the claims, and the like.

### BRIEF DESCRIPTION OF THE DRAWINGS

FIG. 1 is a flow chart showing an evaluation method of an oxide.

FIG. 2 is a cross-sectional view illustrating an analysis method using X-ray diffraction.

FIGS. 3A and 3B show analysis results of oxides by X-ray diffraction.

FIGS. 4A and 4B show electron diffraction patterns of oxides.

FIG. 5 shows a change of crystal parts of oxides owing to electron irradiation.

FIGS. 6A and 6B are a top view and a cross-sectional view which illustrate the transistor of one embodiment of the present invention.

FIGS. 7A and 7B are cross-sectional views each illustrating a transistor of one embodiment of the present invention.

FIGS. 8A and 8B are a top view and a cross-sectional view which illustrate a transistor of one embodiment of the present invention.

FIGS. 9A and 9B are a top view and a cross-sectional view which illustrate a transistor of one embodiment of the present invention.

FIGS. 10A and 10B are a top view and a cross-sectional view which illustrate a transistor of one embodiment of the present invention.

FIGS. 11A and 11B are a top view and a cross-sectional view which illustrate a transistor of one embodiment of the present invention.

FIGS. 12A and 12B are cross-sectional views each illustrating a transistor of one embodiment of the present invention.

FIGS. 13A and 13B are each a circuit diagram of a semiconductor device of one embodiment of the present invention.

FIGS. 14A and 14B are each a circuit diagram of a memory device of one embodiment of the present invention.

FIG. 15 is a block diagram illustrating a CPU of one embodiment of the present invention.

FIG. 16 is a circuit diagram of a memory element of one embodiment of the present invention.

FIGS. 17A to 17C are circuit diagrams of a display device of one embodiment of the present invention.

FIGS. 18A to 18F are views each illustrating an electronic device of one embodiment of the present invention.

FIGS. 19A and 19B are high-resolution TEM images of oxides.

FIG. 20 illustrates a structure model of amorphous InGaZnO₄.

FIGS. 21A, 21B1, 21B2, and 21C illustrate a structure model of InGaZnO₄ including nanocrystals.

FIGS. 22A and 22B show XRD analysis results by calculation.

FIGS. 23A to 23F each show an electron diffraction pattern of an oxide.

FIGS. 24A and 24B each show an electron diffraction pattern of an oxide.

FIGS. 25A and 25B illustrate a deposition model of a CAAC-OS.

FIG. 26 illustrates a deposition model of an nc-OS.

FIG. 27 shows analysis results of an oxide by X-ray diffraction.

FIG. 28 shows analysis results of oxides by X-ray diffraction.

FIG. 29 illustrates HAADF-STEM and ABF-STEM.

FIGS. 30A and 30B are a HAADF-STEM image and an ABF-STEM image, respectively, of InGaZnO₄.

FIG. 31 shows ABF-STEM images and luminance profiles of InGaZnO₄.

FIG. 32 is an ABF-STEM image of a thin film of InGaZnO₄.

### DETAILED DESCRIPTION OF THE INVENTION

Embodiments of the present invention will be described in detail with reference to the drawings. However, the present invention is not limited to the description below, and it is easily understood by those skilled in the art that modes and details disclosed herein can be modified in various ways. Furthermore, the present invention is not construed as being limited to description of the embodiments. In describing structures of the present invention with reference to the drawings, common reference numerals are used for the same portions in different drawings. Note that the same hatched pattern is applied to similar parts, and the similar parts are not especially denoted by reference numerals in some cases.

Note that the size, the thickness of films (layers), or regions in drawings is sometimes exaggerated for clarity.

A voltage usually refers to a potential difference between a given potential and a reference potential (e.g., a source potential or a ground potential (GND)). A voltage can be referred to as a potential and vice versa.

Note that the ordinal numbers such as “first” and “second” in this specification are used for convenience and do not denote the order of steps or the stacking order of layers. Therefore, for example, the term “first” can be replaced with the term “second”, “third”, or the like as appropriate. In addition, the ordinal numbers in this specification and the like do not correspond to the ordinal numbers which specify one embodiment of the present invention in some cases.

Note that a “semiconductor” includes characteristics of an “insulator” in some cases when the conductivity is sufficiently low, for example. Furthermore, a “semiconductor” and an “insulator” cannot be strictly distinguished from each other in some cases because a border between the “semiconductor” and the “insulator” is not clear. Accordingly, a “semiconductor” in this specification can be called an “insulator” in some cases. Similarly, an “insulator” in this specification can be called a “semiconductor” in some cases.

Furthermore, a “semiconductor” includes characteristics of a “conductor” in some cases when the conductivity is sufficiently high, for example. Furthermore, a “semiconductor” and a “conductor” cannot be strictly distinguished from each other in some cases because a border between the “semiconductor” and the “conductor” is not clear. Accordingly, a “semiconductor” in this specification can be called a “conductor” in some cases. Similarly, a “conductor” in this specification can be called a “semiconductor” in some cases.

Note that an impurity in a semiconductor refers to, for example, elements other than the main components of a semiconductor layer. For example, an element with a concentration lower than 0.1 atomic % is an impurity. When an impurity is contained, the density of states (DOS) may be formed in a semiconductor, the carrier mobility may be decreased, or the crystallinity may be decreased, for example. In the case where the semiconductor is an oxide semiconductor, examples of an impurity which changes characteristics of the semiconductor include Group 1 elements, Group 2 elements, Group 14 elements, Group 15 elements, and transition metals other than the main components; specifically, there are hydrogen (included in water), lithium, sodium, silicon, boron, phosphorus, carbon, and nitrogen, for example. When the semiconductor is an oxide semiconductor, oxygen vacancies may be formed by entry of impurities such as hydrogen, for example. Furthermore, when the semiconductor is silicon layer, examples of an impurity which changes the characteristics of the semiconductor include oxygen, Group 1 elements except hydrogen, Group 2 elements, Group 13 elements, and Group 15 elements.

In this specification, the phrase “A has a region with a concentration B” includes, for example, the cases where “the concentration in the entire region in a region of A in the depth direction is B”, “the average concentration in a region of A in the depth direction is B”, “the median value of the concentration in a region of A in the depth direction is B”, “the maximum value of the concentration in a region of A in the depth direction is B”, “the minimum value of the concentration in a region of A in the depth direction is B”, “a convergence value of the concentration in a region of A in the depth direction is B”, and “a concentration in a region of A in which a probable value is obtained in measurement is B”.

In this specification, the phrase “A has a region with a size B, a length B, a thickness B, a width B, or a distance B” includes, for example, “the size, the length, the thickness, the width, or the distance of the entire region in a region of A is B”, “the average value of the size, the length, the thickness, the width, or the distance of a region of A is B”, “the median value of the size, the length, the thickness, the width, or the distance of a region of A is B”, “the maximum value of the size, the length, the thickness, the width, or the distance of a region of A is B”, “the minimum value of the size, the length, the thickness, the width, or the distance of a region of A is B”, “a convergence value of the size, the length, the thickness, the width, or the distance of a region of A is B”, and “the size, the length, the thickness, the width, or the distance of a region of A in which a probable value is obtained in measurement is B”.

Note that the channel length refers to, for example, a distance between a source (a source region or a source electrode) and a drain (a drain region or a drain electrode) in a region where a semiconductor (or a portion where a current flows in a semiconductor when a transistor is on) and a gate electrode overlap with each other or a region where a channel is formed in a top view of the transistor. In one transistor, channel lengths in all regions are not necessarily the same. In other words, the channel length of one transistor is not limited to one value in some cases. Therefore, in this specification, the channel length is any one of values, the maximum value, the minimum value, or the average value in a region where a channel is formed.

The channel width refers to, for example, the length of a portion where a source and a drain face each other in a region where a semiconductor (or a portion where a current flows in a semiconductor when a transistor is on) and a gate electrode overlap with each other or a region where a channel is formed. In one transistor, channel widths in all regions do not necessarily have the same value. In other words, a channel width of one transistor is not fixed to one value in some cases. Therefore, in this specification, a channel width is any one of values, the maximum value, the minimum value, or the average value in a region where a channel is formed.

Note that depending on a transistor structure, a channel width in a region where a channel is formed actually (hereinafter referred to as an effective channel width) is different from a channel width shown in a top view of a transistor (hereinafter referred to as an apparent channel width) in some cases. For example, in a transistor having a three-dimensional structure, an effective channel width is greater than an apparent channel width shown in a top view of the transistor, and its influence cannot be ignored in some cases. For example, in a miniaturized transistor having a three-dimensional structure, the proportion of a channel region formed in a side surface of a semiconductor is higher than the proportion of a channel region formed in a top surface of the semiconductor in some cases. In that case, an effective channel width obtained when a channel is actually formed is greater than an apparent channel width shown in the top view.

In a transistor having a three-dimensional structure, an effective channel width is difficult to measure in some cases. For example, estimation of an effective channel width from a design value requires an assumption that the shape of a semiconductor is known. Therefore, in the case where the shape of a semiconductor is not known accurately, it is difficult to measure an effective channel width accurately.

Therefore, in this specification, in a top view of a transistor, an apparent channel width that is a length of a portion where a source and a drain face each other in a region where a semiconductor and a gate electrode overlap with each other is referred to as a surrounded channel width (SCW) in some cases. Furthermore, in this specification, in the case where the term “channel width” is simply used, it may denote a surrounded channel width or an apparent channel width. Alternatively, in this specification, in the case where the term “channel width” is simply used, it may denote an effective channel width in some cases. Note that the values of a channel length, a channel width, an effective channel width, an apparent channel width, a surrounded channel width, and the like can be determined by obtaining and analyzing a cross-sectional TEM image and the like.

Note that in the case where field-effect mobility, a current value per channel width, and the like of a transistor are obtained by calculation, a surrounded channel width may be used for the calculation. In that case, a value different from one in the case where an effective channel width is used for the calculation is obtained in some cases.

Note that in this specification, the description “A has a shape such that an end portion extends beyond an end portion of B” may indicate, for example, the case where at least one of end portions of A is positioned on an outer side than at least one of end portions of B in a top view or a cross-sectional view. Thus, the description “A has a shape such that an end portion extends beyond an end portion of B” can be alternately referred to as the description “one of end portions of A is positioned on an outer side than one of end portions of B, for example in a top view”.

### <Oxide>

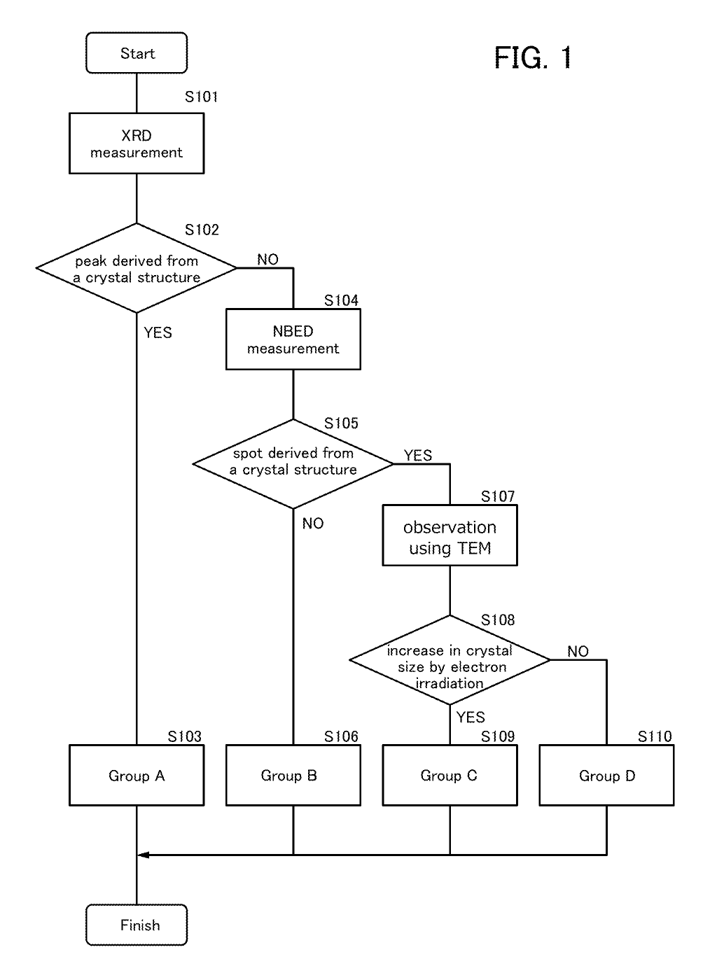

An oxide according to one embodiment of the present invention is described below using FIG. 1.

First, X-ray diffraction (XRD) measurement is performed by irradiating an oxide with X-ray (see Step S101 in FIG. 1). Note that a thin film method is preferably used for the XRD measurement because noise due to a substrate or the like over which the oxide is formed can be reduced.

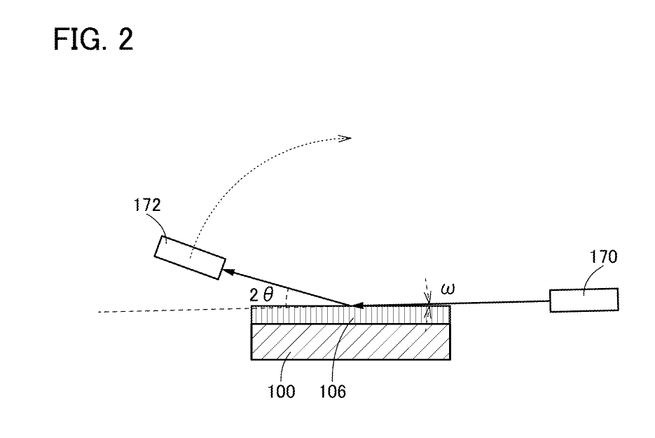

The thin film method is described below. First, as shown in FIG. 2, a sample including an oxide 106 over a substrate 100 is prepared. In the thin film method, an X-ray source 170 is set so that an angle between the X-ray source 170 and a top surface of the sample is an extremely small angle ω. As the X-ray source 170, CuKα ray or synchrotron radiation X-ray may be used, for example. As the angle ω is decreased, noise due to the substrate 100 is decreased. The angle co is set to be greater than or equal to 0.01° and less than or equal to 2°, preferably greater than or equal to 0.05° and less than or equal to 1.5°, more preferably greater than or equal to 0.08° and less than or equal to 1°, for example. Furthermore, as the oxide 106 has a larger thickness, noise due to the substrate 100 is decreased. The thickness of the oxide 106 is set to 50 nm or larger, preferably 100 nm or larger, more preferably 500 nm or larger, still more preferably 1000 nm or larger, for example.

Next, an angle 28 of a detection unit 172 with respect to the top surface of the sample is varied. For example, the angle 28 is varied within a range from 2° to 140°, from 3° to 130°, or from 3° to 100°. In this manner, X-ray diffraction intensity with respect to the angle 28 is obtained. At this time, by increasing the measurement time of the X-ray diffraction, the integrated value of the X-ray diffraction intensity can be increased. For example, in the case of measuring the X-ray diffraction while 2θ is increased in steps of 0.01 degrees, each point may be measured for longer than or equal to one second and shorter than or equal to 20 seconds, or longer than or equal to 3 seconds and shorter than or equal to 15 seconds.

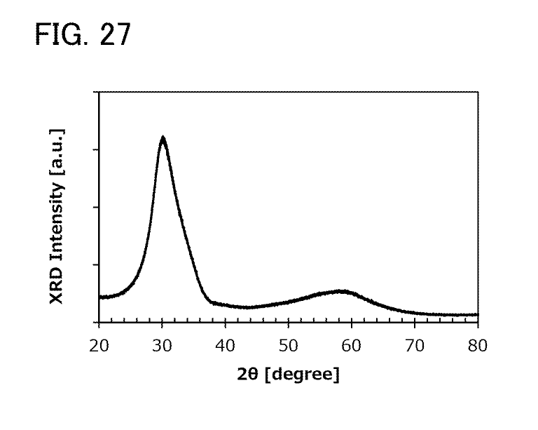

Here, whether or not a peak derived from a crystal structure is observed is determined (see Step S102 in FIG. 1). In the case where the peak derived from a crystal structure is observed, a structure of the oxide is determined to be Group A (see Step S103 in FIG. 1). An oxide of Group A has a crystal structure and alignment along a particular crystal plane. For example, some oxides having a single crystal structure, a polycrystal structure, a CAAC structure, or a microcrystal structure are determined to be Group A. For example, the result of XRD analysis of an In—Ga—Zn oxide represented by Sample 3 is shown in FIG. 27.

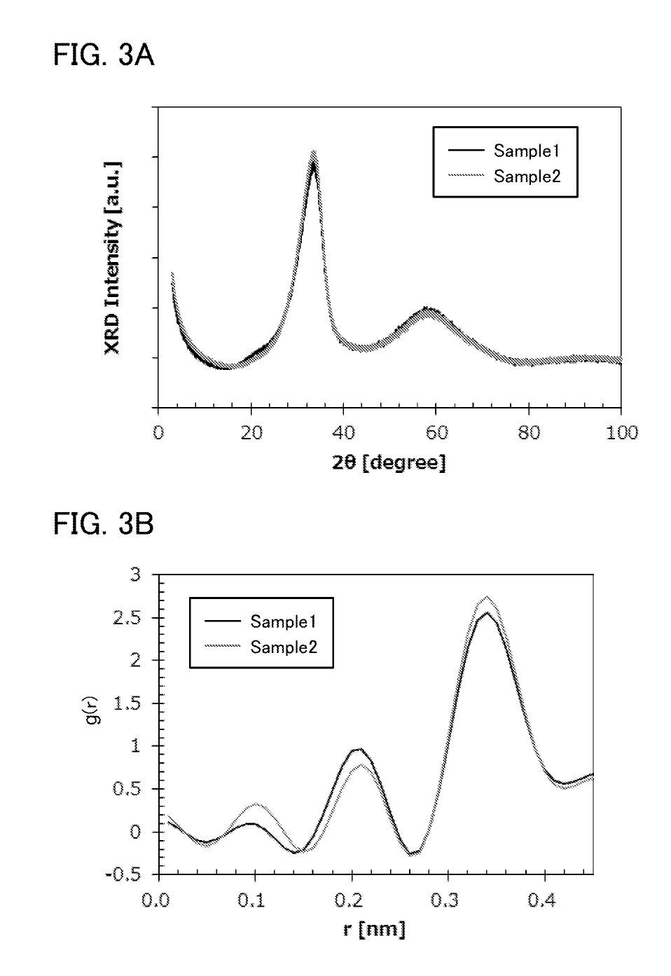

In the case where a peak derived from a crystal structure is not observed, the process proceeds to Step S104 in FIG. 1. Note that even when a peak derived from a crystal structure is not observed, interference derived from a near neighbor atom can be observed in some cases. For example, the results of XRD analysis of In—Ga—Zn oxides represented by Sample 1 and Sample 2 are shown in FIG. 3A.

It is known that X-ray diffraction intensity is expressed by Formula (1).

$$\begin{matrix}[ Formula 1 ] & \\ {I}_{norm} = 〈 {f}^{2} 〉 + 〈 {f}^{2} 〉 {\int }_{0}^{∞} 4 π {r}^{2} \{ ρ ( r ) - {ρ}_{0} \} \frac{sin Qr}{Qr} d r & ( 1 )\end{matrix}$$

Iₙₒᵣₘ, f, ρ₀, ρ(r), Q, and r represent normalized X-ray diffraction intensity, an atomic scattering factor, average number density, number density, a scattering vector, and a distance, respectively.

Note that Iₙₒᵣₘ can be expressed by Formula (2).

$$\begin{matrix}[ Formula 2 ] & \\ {I}_{norm} = a \cdot ( \frac{{I}_{obs} - c}{P} ) - {I}_{Compton} & ( 2 )\end{matrix}$$

I_{obs}, I_{Compton}, P, a, and c represent measured X-ray diffraction intensity, the intensity of incoherent Compton scattering, a polarization correction factor ((1+cos 2θ²)/2), a normalization factor, and a parameter in a model assuming a background independent of the scattering vector Q, respectively.

Note that a and c are calculated by fitting. The fitting may be performed under conditions where r<0.15 nm, a pair distribution function is 0, and the atomic density agrees with calculation results from the measured film density. However, a and c may be calculated by a Krogh-Moe-Norman method and by fitting, respectively.

An interference function i(Q) can be expressed by Formula (3).

$$\begin{matrix}[ Formula 3 ] & \\ i ( Q ) ≡ \frac{{I}_{norm} - 〈 {f}^{2} 〉}{〈 {f}^{2} 〉} & ( 3 )\end{matrix}$$

A pair distribution function can be obtained by the Fourier transform of Q·i(Q). Thus, FIG. 3B can be made from FIG. 3A.

FIG. 3B shows that a peak is observed at a distance r of approximately 0.2 nm in each of Samples 1 and 2. This corresponds to a distance between a metal atom and an oxygen atom of the oxide 106. A peak is observed also at a distance r of approximately 0.35 nm. This corresponds to a distance between a metal atom and a metal atom of the oxide 106. Furthermore, it is shown that the pair distribution function approaches 1 as the distance r increases. That is, it is shown that Samples 1 and 2 do not have a long-range order.

An example in which a peak derived from a crystal structure is not observed by XRD measurement is described below.

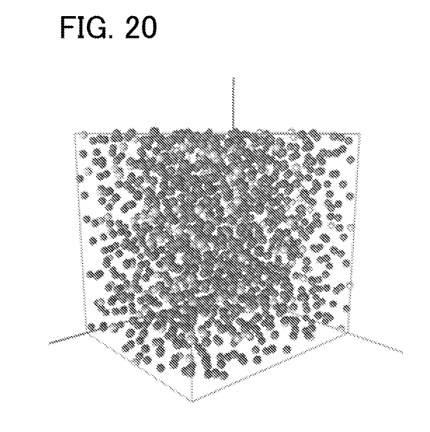

FIG. 20 shows an example of a structure model of amorphous InGaZnO₄ which is made by a melt-quench method in classical molecular dynamics calculation. Specifically, InGaZnO₄ is melted at 4000 K and then the temperature is lowered by 200 K every 0.2 nanoseconds to reach 300 K. Note that the temperature was lowered only by 100 K from 400 K so as to finally reach 300 K. As software for the classical molecular dynamics calculation, “SCIGRESS ME 2.0” was used, and for potential, Born-Mayer-Huggins potential was used.

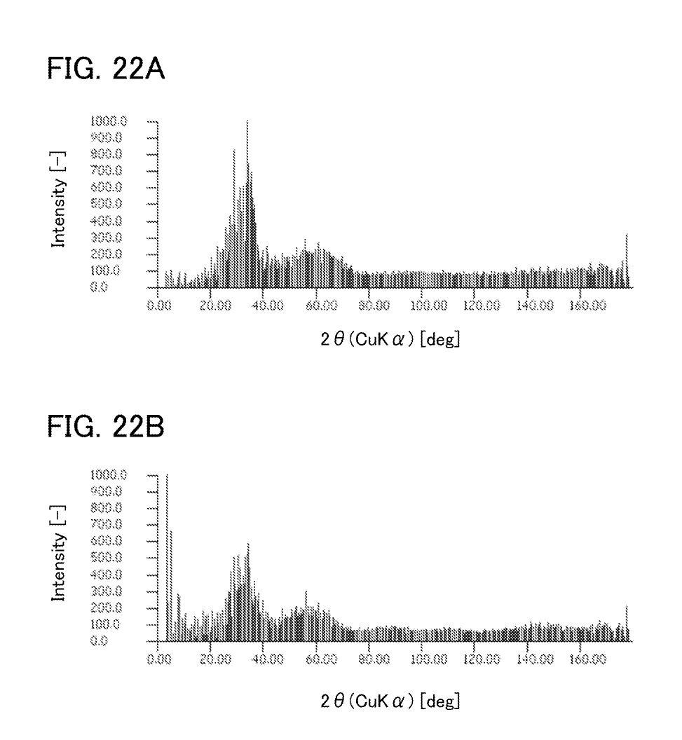

The XRD analysis result shown in FIG. 22A is obtained by the structure analysis of a structure model of amorphous InGaZnO₄ using simulation software jems. Note that for the calculation, CuKα ray with a wavelength of 0.154178 nm is used as the X-ray source. Furthermore, a Debye-Scherrer camera with a diameter of 57.3 mm is used.

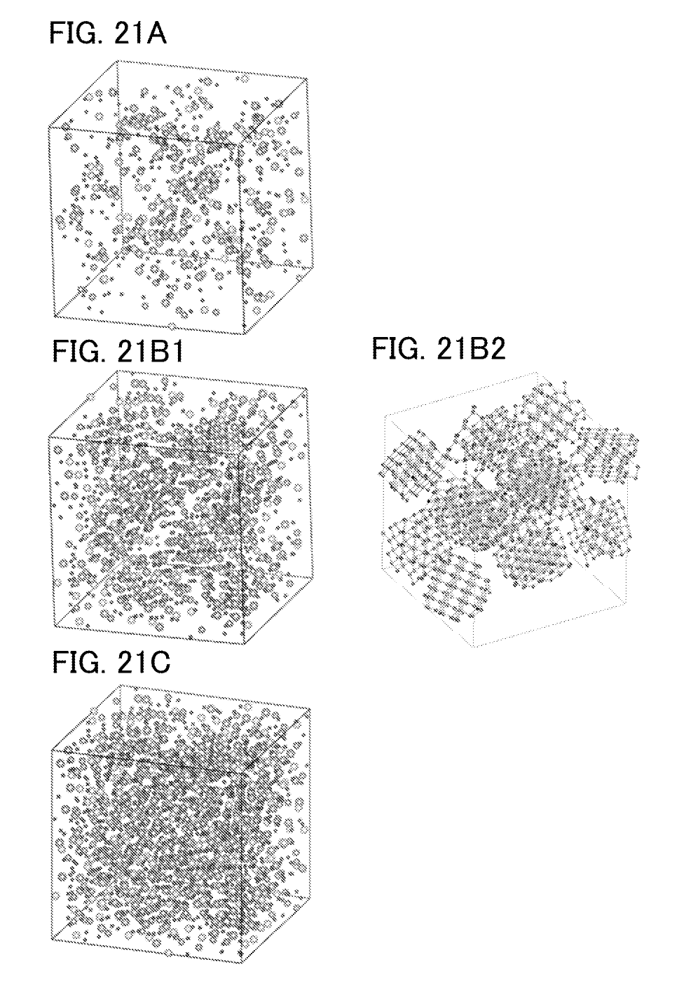

FIG. 21C shows an example of a structure model including nanocrystals in which a plurality of structure models of single crystal InGaZnO₄ (see FIGS. 21B1 and 21B2) is arranged irregularly in a structure model of amorphous InGaZnO₄ (see FIG. 21A). Note that the structure model shown in FIG. 21B2 is made so that the structure model of single crystal InGaZnO₄ is visually recognized more easily than the structure model shown in FIG. 21B1. That is, FIGS. 21B1 and 21B2 show the same structure model.

When the structure model including nanocrystals is analyzed using simulation software jems, XRD analysis results shown in FIG. 22B are obtained. Note that calculation conditions are described above.

As shown in FIGS. 22A and 22B, the XRD analysis results of the structure model of amorphous InGaZnO₄ and the structure model including nanocrystals are similar to each other in, for example, having a maximum value at 2θ of greater than or equal to 20° and less than or equal to 40° and a maximum value at 2θ of greater than or equal to 40° and less than or equal to 80°. Note that in FIG. 22B, a peak is observed at 2θ of less than or equal to 10°. The peak is derived from a periodic structure of a finite structure model and therefore is not derived from the difference in the structure model itself.

The maximum value at 2θ of greater than or equal to 20° and less than or equal to 40° and the maximum value at 2θ of greater than or equal to 40° and less than or equal to 80° are due to the interference derived from a near neighbor atom.

As described above, the structure model of amorphous InGaZnO₄ and the structure model including nanocrystals have the interference derived from a near neighbor atom and do not have a peak derived from a crystal structure.

Next, an electron beam with a probe diameter of 0.3 nm or more and 3 nm or less is transmitted through Samples 1 and 2 to measure a nanobeam electron diffraction (NBED) pattern (see Step S104 in FIG. 1).

Here, whether a spot derived from a crystal structure is not observed (a halo pattern is observed) or a spot derived from a crystal structure is observed is determined (see Step S105 in FIG. 1). In the case where a spot derived from a crystal structure is not observed, the structure of the oxide is determined to be Group B (see Step S106 in FIG. 1). The oxide of Group B does not have a crystal structure. For example, some oxides having an amorphous structure are determined to be Group B.

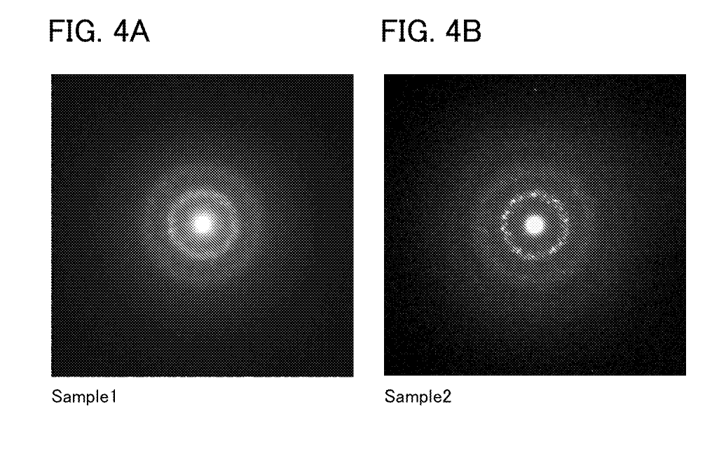

In the case where a spot derived from a crystal structure is observed, the process proceeds to Step S107 in FIG. 1. Note that a particular crystal structure cannot be identified in some cases even when a spot derived from a crystal structure is observed. For example, in the case where a plurality of crystal parts is included and the crystal parts each have no alignment along a particular crystal plane, an electron diffraction pattern in which spots derived from various crystal planes appear to overlap with each other is observed. For example, FIGS. 4A and 4B show electron diffraction patterns of In—Ga—Zn oxides represented by Sample 1 and Sample 2, respectively. Note that an electron beam with a probe diameter of 1 nm is used to measure the electron diffraction patterns.

As shown in FIGS. 4A and 4B, the observed electron diffraction patterns of Sample 1 and Sample 2 each have a region with high luminance in a circular (ring) pattern. Furthermore, the observed electron diffraction patterns each have a plurality of spots in the ring region. It is shown that the spots in Sample 2 are clearer than those in Sample 1. Therefore, Sample 2 is likely to have higher crystallinity than Sample 1.

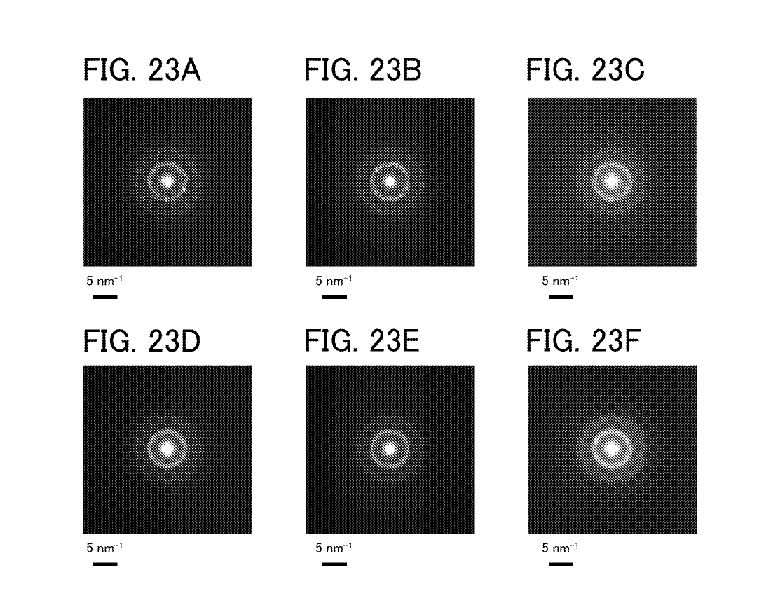

Note that in the sample having a crystal structure, a spot derived from a crystal structure is observed in some cases and a spot derived from a crystal structure is not observed in some other cases, depending on an electron diffraction method. Furthermore, in some cases, the arrangement of the spot derived from a crystal structure is varied depending on a measurement method. Examples of such cases are described below using Sample 2. For example, FIGS. 23A, 23B, 23C, 23D, 23E, and 23F are electron diffraction patterns observed using electron beams having probe diameters of 1 nm, 5 nm, 10 nm, 25 nm, 50 nm, and 100 nm, respectively. Note that the thickness of Sample 2 is 34 nm.

It is shown from FIGS. 23A to 23F that a spot derived from a crystal structure is clearer as the probe diameter of the electron beam is decreased to 10 nm, 5 nm, and 1 nm; in contrast, a spot derived from a crystal structure is more unclear as the probe diameter of the electron beam is increased to 25 nm, 50 nm, and 100 nm. Therefore, in Sample 2, a spot derived from a crystal structure is observed in the electron diffraction pattern observed using the electron beam having a probe diameter of 5 nm or less, whereas a spot derived from a crystal structure is not observed in the electron diffraction pattern observed using the electron beam having a probe diameter of 25 nm or more. That is, the selection of an appropriate probe diameter is required for a crystal structure analysis.

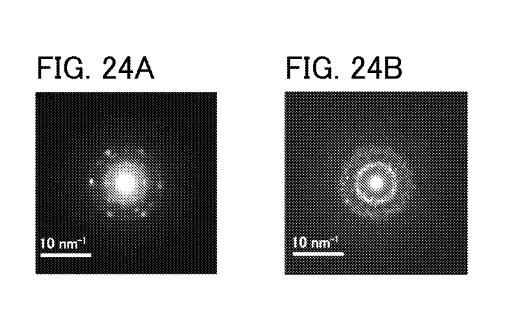

Furthermore, electron diffraction patterns shown in FIGS. 24A and 24B can be observed in Sample 2 having a thickness of less than 10 nm and Sample 2 having a thickness of 45 nm, respectively, in the case of using an electron beam having a probe diameter of 1 nm. As shown in FIG. 24A, an electron diffraction pattern in which spots are arranged in an approximately hexagonal shape is observed in Sample 2 having a thickness of less than 10 nm. This implies that Sample 2 has at least one crystal structure in the range of less than 10 nm in thickness. Furthermore, as shown in FIG. 24B, order is not observed in the arrangement of spots in Sample 2 having a thickness of 45 nm. This implies that a plurality of crystal structures is included in Sample 2 having a thickness of 45 nm and that the orientation of the plurality of crystal structures is not uniform. That is, the selection of a sample having an appropriate thickness is required for the detailed analysis of a crystal structure. However, it is clear that a spot derived from a crystal structure is included also in Sample 2 having a thickness of 45 nm.

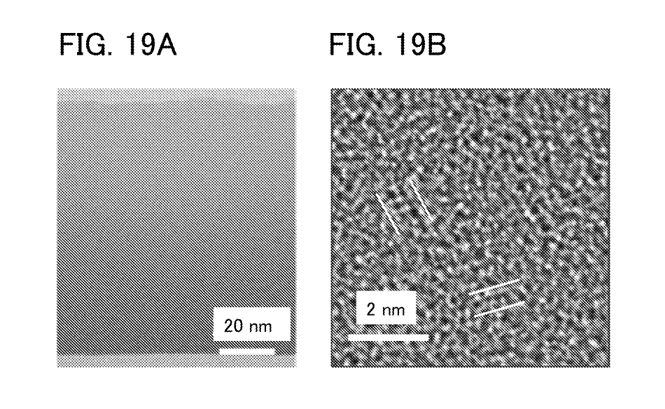

Next, combined analysis images (also referred to as high-resolution TEM images) of bright-field images and diffraction patterns of Sample 1 and Sample 2 are observed (see FIGS. 19A and 19B). As described above, an electron diffraction pattern derived from a crystal structure is observed in each of Sample 1 and Sample 2. Therefore, a crystal part (see FIG. 19B) can be observed in the high-resolution TEM image.

The crystal part size in Sample 1 and Sample 2 can be measured using high-resolution TEM images. For example, an InGaZnO₄ crystal has a layered structure in which two Ga—Zn—O layers are included between In—O layers. A unit cell of the InGaZnO₄ crystal has a structure in which nine layers of three In—O layers and six Ga—Zn—O layers are layered in the c-axis direction. Accordingly, the spacing between these adjacent layers is equivalent to the lattice spacing on the (009) plane (also referred to as d value). The value is calculated to 0.29 nm from crystal structure analysis. Thus, each of the lattice fringes in which the spacing therebetween is from 0.28 nm to 0.30 nm can be regarded to correspond to the a-b plane of the InGaZnO₄ crystal, focusing on the lattice fringes in the high-resolution TEM image. The maximum length of the region in which the lattice fringes are observed is regarded as the size of a crystal part in an oxide. Note that the crystal part whose size is 0.8 nm or larger is selectively evaluated.

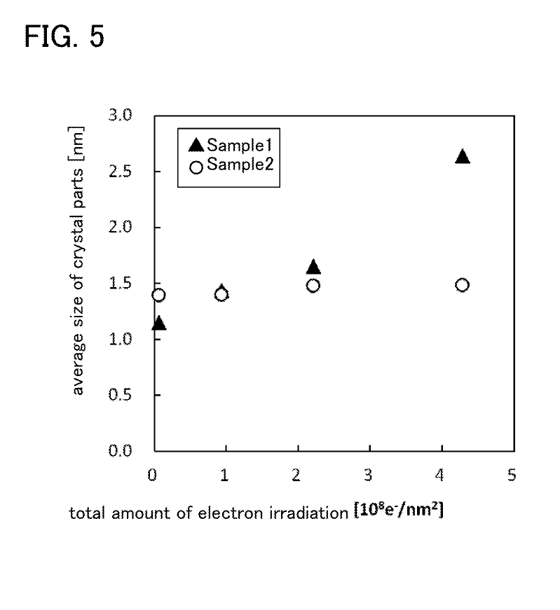

FIG. 5 shows examination results of change in average size of crystal parts (20-40 points) in Sample 1 and Sample 2 using the high-resolution TEM image. Here, it is determined whether or not a crystal size is increased by electron irradiation (see Step S108 in FIG. 1). Note that the length of the crystal part in the longitudinal direction is measured as a crystal part size. FIG. 5 shows that the crystal part size in Sample 1 increases with an increase in the cumulative electron dose. Specifically, the crystal part of approximately 1.2 nm at the start of TEM observation grows to a size of approximately 2.6 nm at the total amount of electron irradiation of 4.2×10⁸ e⁻/nm². In contrast, the crystal part size in Sample 2 shows little change from the start of electron irradiation to a cumulative electron dose of 4.2×10⁸ e⁻/nm² regardless of the cumulative electron dose. It is shown that the change in the crystal part size is specifically less than 10%, more specifically less than 7%.

Furthermore, in FIG. 5, by linear approximation of the change in the crystal part size in Sample 1 and Sample 2 and extrapolation to the total amount of electron irradiation of 0 e⁻/nm², the average size of the crystal part is found to be a positive value. This means that the crystal parts exist in Sample 1 and Sample 2 before TEM observation.

Here, Sample 1 whose crystal size is increased by electron irradiation is determined to be Group C (see Step S109 in FIG. 1). An oxide of Group C has a crystal structure and no alignment along a particular crystal plane. For example, some oxides having a physical property between an amorphous structure and a microcrystal structure are determined to be Group C. In some cases, an oxide determined to be Group C has a space large enough to allow crystal growth to occur therein by electron irradiation (the space is also referred to as a void). Therefore, such an oxide has low stability and might be unsuitable for a semiconductor of a transistor or the like.

Sample 2 whose crystal size is not increased by electron irradiation is determined to be Group D (see Step S110 in FIG. 1). An oxide of Group D has a crystal structure and no alignment along a particular crystal plane. For example, some oxides having a microcrystal structure are determined to be Group D. Furthermore, the oxide determined to be Group D can be referred to as an oxide including a nanocrystal (nc) structure because the size of a crystal part included in Sample 2 is approximately several nanometers. In an oxide determined to be Group D, a space between crystal parts might be small or hardly exist because crystal growth does not occur by electron irradiation. Therefore, such an oxide has higher stability than an oxide determined to be Group C and is suitable for a semiconductor of a transistor or the like.

In some cases, Group C and Group D can be distinguished from each other also by measuring the density of oxides. For example, if the composition of an oxide is determined, the structure of the oxide can be estimated from a comparison between the density of the oxide and the density of a single-crystal oxide having the same composition as the oxide. For example, the density of an oxide determined to be Group C is higher than or equal to 78.6% and lower than 92.3% of that of a single-crystal oxide. For example, the density of an oxide determined to be Group D is higher than or equal to 92.3% and lower than 100% of that of a single-crystal oxide.

Specific examples of the above description are given. For example, in the case of an oxide having an atomic ratio of In to Ga and Zn is 1:1:1, the density of single crystal of InGaZnO₄ with a rhombohedral crystal structure is 6.357 g/cm³. Accordingly, for example, in the oxide in which the atomic ratio of In to Ga and Zn is 1:1:1, the density of the oxide determined to be Group C is higher than or equal to 5.0 g/cm³ and lower than 5.9 g/cm³, and the density of the oxide determined to be Group D is higher than or equal to 5.9 g/cm³ and lower than 6.3 g/cm³.

However, there might be no single crystal oxide semiconductor having the same composition as the oxide semiconductor. In that case, single crystal oxides with different compositions are combined in an adequate ratio to calculate the density equivalent to that of a single crystal oxide with the desired composition. The density of the single crystal oxide having the desired composition can be calculated using a weighted average according to the combination ratio of the single crystal oxides with different compositions. Note that it is preferable to combine as few kinds of single crystal oxides as possible for density calculation.

### <Deposition Model>

Examples of deposition models of a CAAC-OS and an nc-OS are described below.

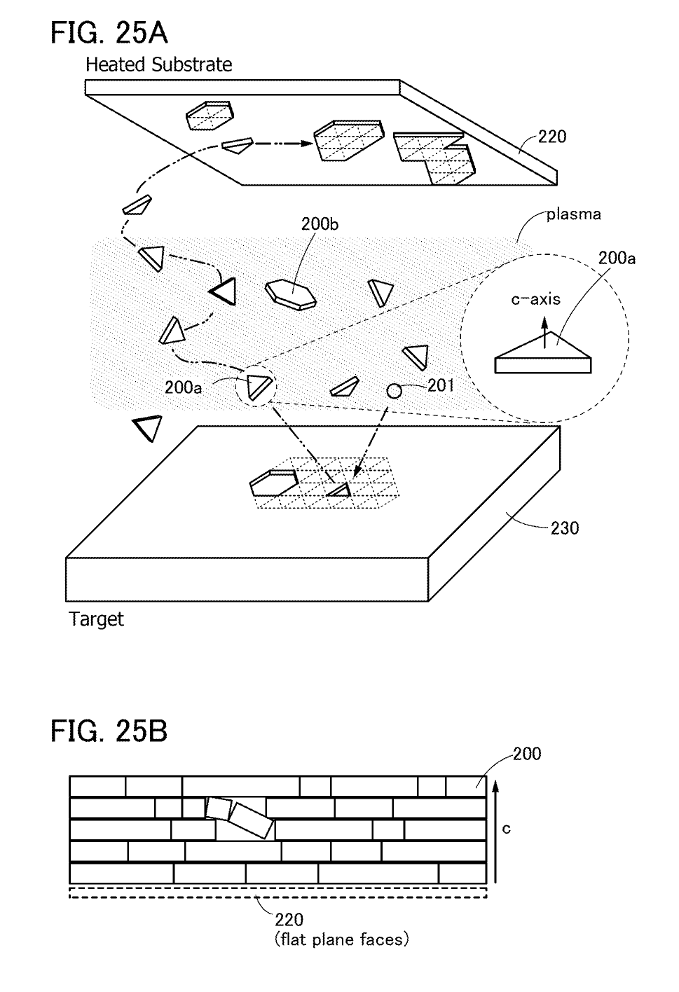

FIG. 25A is a schematic diagram of a deposition chamber illustrating a state where a CAAC-OS is deposited by a sputtering method.

A target 230 is attached to a backing plate. Under the target 230 and the backing plate, a plurality of magnets are placed. The plurality of magnets generate a magnetic field over the target 230. A sputtering method in which the disposition speed is increased by utilizing a magnetic field of magnets is referred to as a magnetron sputtering method.

The target 230 has a polycrystalline structure in which a cleavage plane exists in at least one crystal grain. Note that the details of the cleavage plane are described later.

The substrate 220 is placed to face the target 230, and the distance d (also referred to as a target-substrate distance (T-S distance)) is greater than or equal to 0.01 m and less than or equal to 1 m, preferably greater than or equal to 0.02 m and less than or equal to 0.5 m. The deposition chamber is mostly filled with a deposition gas (e.g., an oxygen gas, an argon gas, or a mixed gas containing oxygen at 50 vol % or higher) and controlled to higher than or equal to 0.01 Pa and lower than or equal to 100 Pa, preferably higher than or equal to 0.1 Pa and lower than or equal to 10 Pa. Here, discharge starts by application of a voltage at a constant value or higher to the target 230, and plasma is observed. Note that the magnetic field over the target 230 forms a high-density plasma region. In the high-density plasma region, the deposition gas is ionized, so that an ion 201 is generated. Examples of the ion 201 include an oxygen cation (O⁺) and an argon cation (Ar⁺).

The ion 201 is accelerated toward the target 230 side by an electric field, and collides with the target 230 eventually. At this time, a pellet 200a and a pellet 200b which are flat-plate-like or pellet-like sputtered particles are separated and sputtered from the cleavage plane. Note that structures of the pellet 200a and the pellet 200b may be distorted by an impact of collision of the ion 201.

The pellet 200a is a flat-plate-like or pellet-like sputtered particle having a triangle plane, e.g., a regular triangle plane. The pellet 200b is a flat-plate-like or pellet-like sputtered particle having a hexagon plane, e.g., a regular hexagon plane. Note that a flat-plate-like or pellet-like sputtered particle such as the pellet 200a and the pellet 200b is collectively called a pellet 200. The shape of a flat plane of the pellet 200 is not limited to a triangle or a hexagon. For example, the flat plane may have a shape formed by combining greater than or equal to 2 and less than or equal to 6 triangles. For example, a square (rhombus) is formed by combining two triangles (regular triangles) in some cases.

The thickness of the pellet 200 is determined depending on the kind of deposition gas and the like. The thicknesses of the pellets 200 are preferably uniform; the reasons thereof are described later. In addition, the sputtered particle preferably has a pellet shape with a small thickness as compared to a dice shape with a large thickness.

The pellet 200 receives a charge when passing through the plasma, so that side surfaces thereof are negatively or positively charged in some cases. The pellet 200 includes oxygen atoms on its side surfaces, and the oxygen atoms may be negatively charged. When the side surfaces are charged in the same polarity, charges repel each other, and accordingly, the pellet 200 can maintain a flat-plate shape. In the case where a CAAC-OS is an In—Ga—Zn oxide, there is a possibility that an oxygen atom bonded to an indium atom is negatively charged. There is another possibility that an oxygen atom bonded to an indium atom, a gallium atom, or a zinc atom is negatively charged.

As illustrated in FIG. 25A, the pellet 200 flies like a kite in plasma and flutters up to the substrate 220, for example. Since the pellets 200 are charged, when the pellet 200 gets close to a region where another pellet 200 has already been deposited, repulsion is generated. Here, above the substrate 220, a magnetic field is generated in a direction parallel to a top surface of the substrate 220. A potential difference is given between the substrate 220 and the target 230, and accordingly, current flows from the substrate 220 toward the target 230. Thus, the pellet 200 is given a force (Lorentz force) on a surface of the substrate 220 by an effect of the magnetic field and the current. This is explainable with Fleming's left-hand rule. In order to increase a force applied to the pellet 200, it is preferable to provide, on the top surface, a region where the magnetic field in a direction parallel to the top surface of the substrate 220 is 10 G or higher, preferably 20 G or higher, further preferably 30 G or higher, still further preferably 50 G or higher. Alternatively, it is preferable to provide, on the top surface, a region where the magnetic field in a direction parallel to the top surface of the substrate 220 is 1.5 times or higher, preferably twice or higher, further preferably 3 times or higher, still further preferably 5 times or higher as high as the magnetic field in a direction perpendicular to the top surface of the substrate 220.

Furthermore, the substrate 220 is heated, and resistance such as friction between the pellet 200 and the substrate 220 is low. As a result, the pellet 200 glides above the surface of the substrate 220. The glide of the pellet 200 is caused in a state where the flat plane faces the substrate 220. Then, when the pellet 200 reaches the side surface of another pellet 200 that has been already deposited, the side surfaces of the pellets 200 are bonded. At this time, the oxygen atom on the side surface of the pellet 200 is released. With the released oxygen atom, oxygen vacancies in a CAAC-OS are filled in some cases; thus, the CAAC-OS has a low density of defect states. Note that in some cases, oxygen vacancies in an oxide semiconductor can be evaluated by annular bright-field scan transmission electron microscopy (ABF-STEM). The evaluation of oxygen vacancies by ABF-STEM is described later.

Furthermore, the pellet 200 is heated over the substrate 220, whereby atoms are rearranged, and the structure distortion caused by the collision of the ion 201 can be reduced. The pellet 200 whose structure distortion is reduced is substantially a single crystal. Even when the pellets 200 are heated after being bonded, expansion and contraction of the pellet 200 itself hardly occur, which is caused by turning the pellet 200 to be substantially a single crystal. Thus, formation of defects such as a grain boundary due to expansion of a space between the pellets 200 can be prevented, and accordingly, generation of crevasses can be prevented. Furthermore, the space is filled with elastic metal atoms and the like, whereby the elastic metal atoms and the like connect the pellets 200 which are not aligned with each other as a highway.

It is considered that as shown in such a model, the pellets 200 are deposited over the substrate 220. Thus, a CAAC-OS can be deposited even when a surface over which a film is formed (film formation surface) does not have a crystal structure, which is different from film deposition by epitaxial growth. For example, even when a top surface (film formation surface) of the substrate 220 has an amorphous structure, a CAAC-OS can be formed.

Furthermore, it is found that in formation of the CAAC-OS, the pellets 200 are arranged in accordance with a shape of the top surface of the substrate 220 that is the film formation surface even when the film formation surface has unevenness. For example, in the case where the top surface of the substrate 220 is flat at the atomic level, the pellets 200 are arranged so that flat planes parallel to the a-b plane face downwards as illustrated in FIG. 25B; thus, a layer with a uniform thickness, flatness, and high crystallinity is formed. By stacking n layers (n is a natural number), the CAAC-OS can be obtained.

In the case where the top surface of the substrate 220 has unevenness, a CAAC-OS in which n layers (n is a natural number) in each of which the pellets 200 are arranged along the convex surface are stacked is formed. Since the substrate 220 has unevenness, a gap is easily generated between the pellets 200 in the CAAC-OS in some cases. Note that owing to intermolecular force, the pellets 200 are arranged so that a gap between the pellets is as small as possible even over the unevenness surface. Therefore, even when the film formation surface has unevenness, a CAAC-OS with high crystallinity can be formed.

Accordingly, a CAAC-OS does not need laser crystallization, and deposition can be uniformly performed even in the case of a large-sized glass substrate.

Since the CAAC-OS is deposited according to such a model, the sputtered particles preferably have a pellet shape with a small thickness. Note that in the case where the sputtered particles have a dice shape with a large thickness, planes of the particles facing the substrate 220 are not the same and thus, the thickness and the orientation of the crystals cannot be uniform in some cases.

According to the above-described deposition model, a CAAC-OS having high crystallinity can be formed even over a formation surface having an amorphous structure.

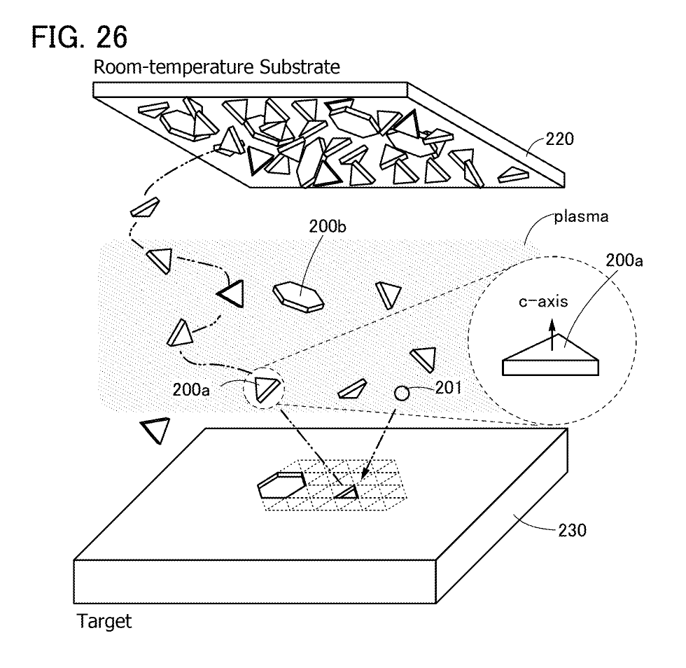

An nc-OS can be understood with a deposition model illustrated in FIG. 26. Note that a difference between FIG. 26 and FIG. 25A lies only in whether the substrate 220 is heated.

Thus, the substrate 220 is not heated, and resistance such as friction between the pellet 200 and the substrate 220 is high. As a result, the pellets 200 cannot glide on the surface of the substrate 220 and are stacked randomly, so that an nc-OS can be obtained.

### <Oxygen Vacancies of Oxide Semiconductor>

An example in which oxygen vacancies are evaluated by analyzing a structure of an oxide semiconductor is described below.

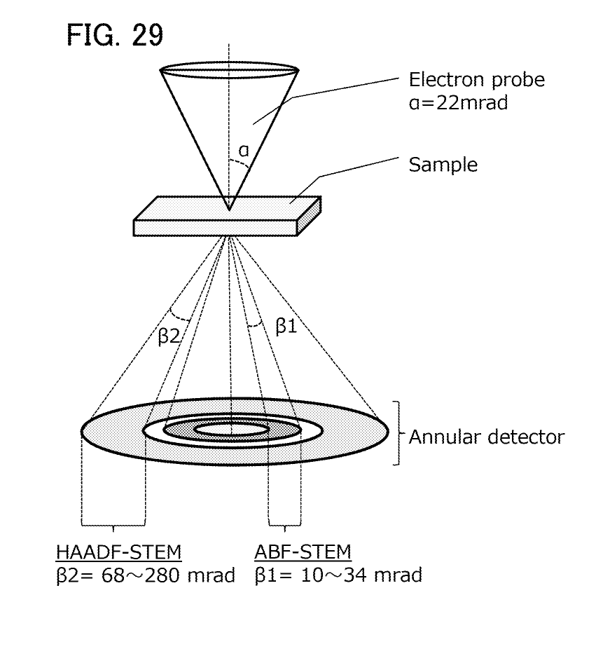

The structure of atoms can be analyzed with a high-resolution scanning transmission electron microscope using a spherical aberration corrector function. An example of an analysis method is high-angle annular dark-field scanning transmission electron microscopy (HAADF-STEM) in which a focused electron beam is scanned and electrons scattered at high angles (e.g., an angle β2 shown in FIG. 29 is in the range of 68 mrad to 280 mrad) are selectively detected with an annular detector. As the atomic number (Z) is larger, the proportion of the electron beam scattered at high angles is increased. Therefore, by HAADF-STEM, higher contrast (also referred to as Z contrast) can be obtained in proportion to the square of an atomic number.

Another example of the analysis method is ABF-STEM in which electrons scattered at low angles (e.g., an angle 131 shown in FIG. 29 is in the range of 10 mrad to 34 mrad) or transmitted electrons are selectively detected with an annular detector. In ABF-STEM, in the case where a column of light elements exists in a depth direction at the time of scanning an electron beam, because the electron beam is transmitted through a sample without being spread, the proportion of electrons that reach inner hole (non-detection portion) of the annular detector is high. Furthermore, the proportion of electrons that are scattered and reach the annular detector is low because the atomic number is small. In the case where a column of heavy elements exists, the proportion of electrons scattered at high angles is high; therefore, the proportion of electrons that reach the annular detector is relatively low. In the case where a column of light elements and a column of heavy elements do not exist, because the electron beam is transmitted through a sample while being spread, the proportion of electrons that reach the annular detector is high. As described above, in the case where the column of light elements exists or the case where the column of heavy elements exists, the proportion of electrons that enter the annular detector is decreased; therefore, low contrast can be obtained in each case.

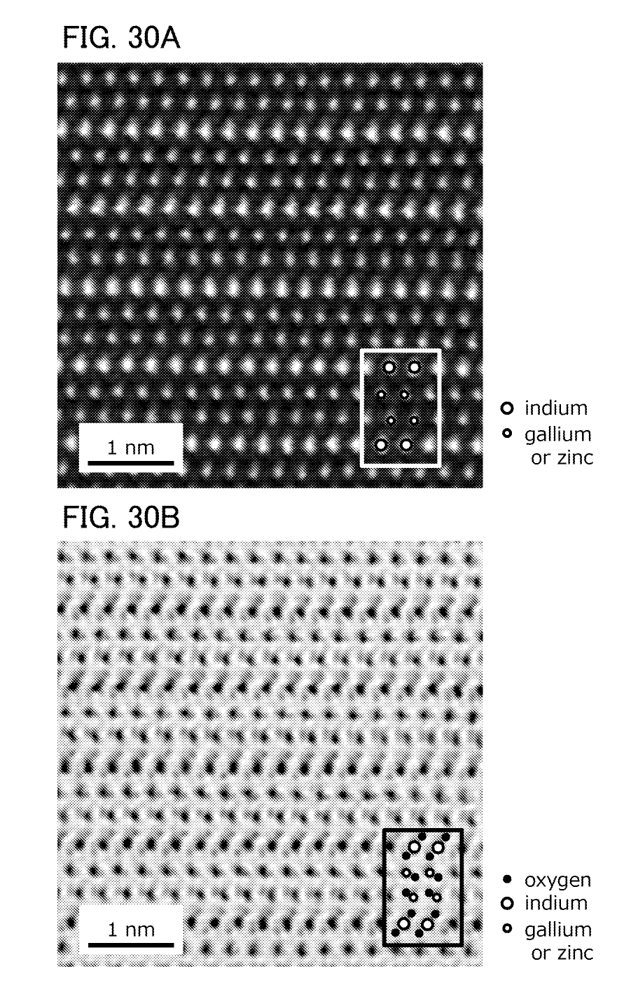

The observed sample is a crystal of InGaZnO₄. FIG. 30A is a HAADF-STEM image, and FIG. 30B is an ABF-STEM image. The HAADF-STEM image and the ABF-STEM image show the same location. For easy understanding, schematic atomic arrangement is shown in a surrounded portion in the lower right side of each image. Note that an atomic resolution analytical electron microscope JEM-ARM200F manufactured by JEOL Ltd. is used for the observation.

As shown in FIG. 30A, a column of indium and a column of gallium and zinc (a column in which gallium and zinc are mixed) can be observed in the HAADF-STEM image. Thus, in the HAADF-STEM image, the columns of indium, gallium, and zinc which are heavy elements show extremely high contrast, whereas the contrast of a column of oxygen which is a light element is not clear.

On the other hand, as shown in FIG. 30B, a column of oxygen can be observed in addition to the column of indium and the column of gallium and zinc, in the ABF-STEM image.

Thus, by ABF-STEM, the column of oxygen in InGaZnO₄ can be clearly observed. Next, the case where an oxygen vacancy or the fluctuation of arrangement exists in the column of oxygen is described.

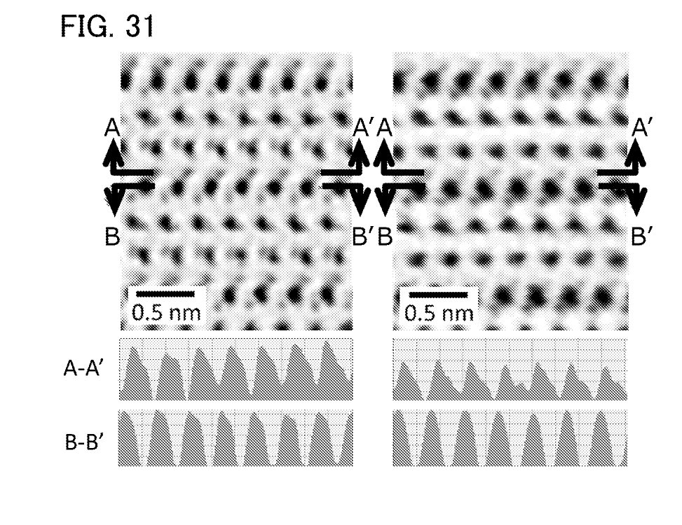

For example, ABF-STEM images on the right side and the left side of FIG. 31 show comparison between before and after heat treatment under a nitrogen atmosphere at 450° C. for one hour. Furthermore, luminance profiles along A-A′ and B-B′ are shown on the lower side of FIG. 31. Note that the luminance profiles along A-A′ include a column of oxygen, and the luminance profiles along B-B′ include a column of indium. In the luminance profiles in FIG. 31, luminance is adjusted so that the luminance contrast between the highest luminance and the lowest luminance is the same in the luminance profiles along B-B′ on the left side and the right side.

Then, the luminance profiles along A-A′ on the right side and the left side of FIG. 31 are compared with each other. The difference in height between the highest luminance and the lowest luminance in the luminance profile on the right side (after the heat treatment) is smaller than in the luminance profile on the left side (before the heat treatment). This suggests that the heat treatment causes the generation of oxygen vacancies or the fluctuation of the arrangement of oxygen atoms in the column of oxygen.

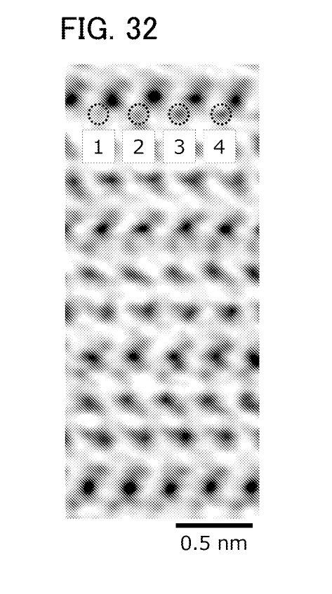

FIG. 32 is an ABF-STEM image of a thin film of InGaZnO₄ having oxygen vacancies. In oxygen columns denoted by 1, 2, 3, and 4 in FIG. 32, the oxygen column denoted by 1 has lower contrast than the other oxygen columns, suggesting that the oxygen column denoted by 1 has a high proportion of oxygen vacancies.

As described above, oxygen vacancies in an oxide semiconductor can be evaluated by ABF-STEM.

### <Transistor>

A transistor of one embodiment of the present invention is described below.

Note that a transistor of one embodiment of the present invention preferably includes the above-described oxide determined to be Group D.

### <Transistor Structure 1>

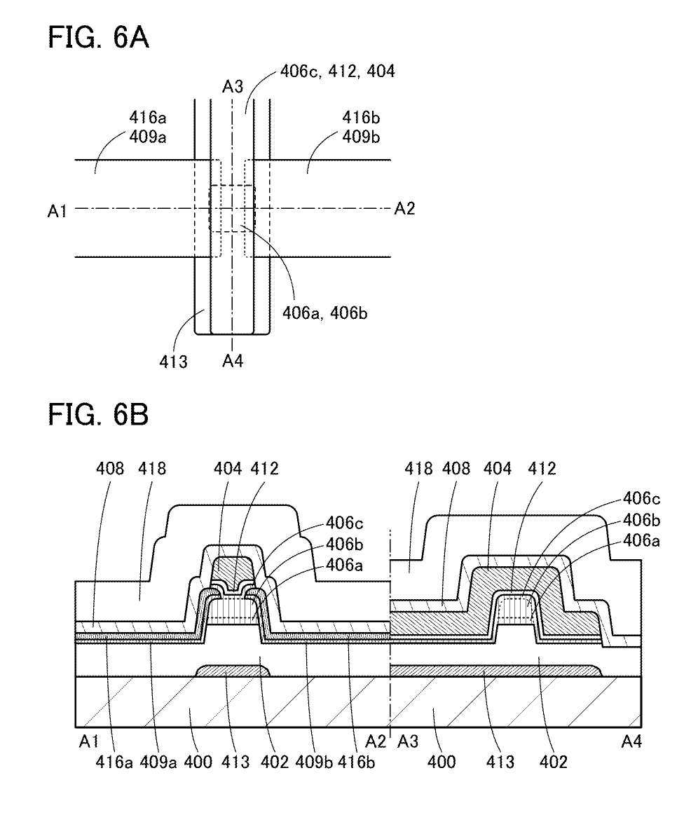

FIGS. 6A and 6B are a top view and a cross-sectional view of a transistor of one embodiment of the present invention. FIG. 6A is a top view and FIG. 6B is a cross-sectional view taken along dashed-dotted line A1-A2 and dashed-dotted line A3-A4 in FIG. 6A. Note that for simplification of the drawing, some components are not illustrated in the top view in FIG. 6A.

The transistor in FIGS. 6A and 6B includes a conductor 413 over a substrate 400, an insulator 402 having a projection over the substrate 400 and the conductor 413, a semiconductor 406a over the projection of the insulator 402, a semiconductor 406b over the semiconductor 406a, a layer 409a and a layer 409b which are in contact with a top surface and a side surface of the semiconductor 406b and which are arranged to be apart from each other, a conductor 416a over the layer 409a, a conductor 416b over the layer 409b, a semiconductor 406c over the semiconductor 406b, the layer 409a, the layer 409b, the conductor 416a, and the conductor 416b, an insulator 412 over the semiconductor 406c, a conductor 404 over the insulator 412, an insulator 408 over the conductor 416a, the conductor 416b, and the conductor 404, and an insulator 418 over the insulator 408. Here, the conductor 413 is part of the transistor, but is not limited to this. For example, the conductor 413 may be a component independent of the transistor.

Note that the semiconductor 406c is in contact with at least a top surface and a side surface of the semiconductor 406b in the cross section taken along line A3-A4. Furthermore, the conductor 404 faces the top surface and the side surface of the semiconductor 406b through the semiconductor 406c and the insulator 412 in the cross section taken along line A3-A4. The conductor 413 faces a bottom surface of the semiconductor 406b with the insulator 402 provided therebetween. The insulator 402 does not necessarily include a projection. The semiconductor 406c, the insulator 408, the insulator 418, the layer 409a, and/or the layer 409b are/is not necessarily provided.

The semiconductor 406b serves as a channel formation region of the transistor. The conductor 404 serves as a first gate electrode (also referred to as a front gate electrode) of the transistor. The conductor 413 serves as a second gate electrode (also referred to as a back gate electrode) of the transistor. The conductor 416a and the conductor 416b serve as a source electrode and a drain electrode of the transistor. The insulator 408 functions as a barrier layer. The insulator 408 has, for example, a function of blocking oxygen and/or hydrogen. Alternatively, the insulator 408 has, for example, a higher capability of blocking oxygen and/or hydrogen than the semiconductor 406a and/or the semiconductor 406c.

The insulator 402 is preferably an insulator containing excess oxygen.

The insulator containing excess oxygen means an insulator from which oxygen is released by heat treatment, for example. The silicon oxide layer containing excess oxygen means a silicon oxide layer which can release oxygen by heat treatment or the like, for example. Therefore, the insulator 402 is an insulator in which oxygen can be moved. In other words, the insulator 402 may be an insulator having an oxygen-transmitting property. For example, the insulator 402 may be an insulator having a higher oxygen-transmitting property than the semiconductor 406a.

The insulator containing excess oxygen has a function of reducing oxygen vacancies in the semiconductor 406b in some cases. Such oxygen vacancies form DOS in the semiconductor 406b and serve as hole traps or the like. In addition, hydrogen comes into the site of such oxygen vacancies and forms electrons serving as carriers. Therefore, by reducing the oxygen vacancies in the semiconductor 406b, the transistor can have stable electrical characteristics.

Here, an insulator from which oxygen is released by heat treatment may release oxygen, the amount of which is higher than or equal to 1×10¹⁸ atoms/cm³, higher than or equal to 1×10¹⁹ atoms/cm³, or higher than or equal to 1×10²⁰ atoms/cm³ (converted into the number of oxygen atoms) in TDS analysis in the range of a surface temperature of 100° C. to 700° C. or 100° C. to 500° C.

Here, the method for measuring the amount of released oxygen using TDS analysis is described below.

The total amount of released gas from a measurement sample in TDS analysis is proportional to the integral value of the ion intensity of the released gas. Then, comparison with a reference sample is made, whereby the total amount of released gas can be calculated.

For example, the number of released oxygen molecules (N_{O2}) from a measurement sample can be calculated according to the following formula using the TDS results of a silicon substrate containing hydrogen at a predetermined density, which is a reference sample, and the TDS results of the measurement sample. Here, all gases having a mass-to-charge ratio of 32 which are obtained in the TDS analysis are assumed to originate from an oxygen molecule. Note that CH₃OH, which is a gas having the mass-to-charge ratio of 32, is not taken into consideration because it is unlikely to be present. Furthermore, an oxygen molecule including an oxygen atom having a mass number of 17 or 18 which is an isotope of an oxygen atom is also not taken into consideration because the proportion of such a molecule in the natural world is minimal.

N_{O2}=N_{H2}/S_{H2}×S_{O2}×α,

The value N_{H2} is obtained by conversion of the number of hydrogen molecules desorbed from the reference sample into densities. The value S_{H2} is the integral value of ion intensity in the case where the reference sample is subjected to the TDS analysis. Here, the reference value of the reference sample is set to N_{H2}/S_{H2}. The value S_{O2} is the integral value of ion intensity when the measurement sample is analyzed by TDS. The value a is a coefficient affecting the ion intensity in the TDS analysis. Refer to Japanese Published Patent Application No. H6-275697 for details of the above formula. The amount of released oxygen is measured with a thermal desorption spectroscopy apparatus produced by ESCO Ltd., EMD-WA1000S/W using a silicon substrate containing hydrogen atoms at 1×10¹⁶ atoms/cm², for example, as the reference sample.

Furthermore, in the TDS analysis, oxygen is partly detected as an oxygen atom. The ratio between oxygen molecules and oxygen atoms can be calculated from the ionization rate of the oxygen molecules. Note that since the above a includes the ionization rate of the oxygen molecules, the amount of the released oxygen atoms can also be estimated through the evaluation of the amount of the released oxygen molecules.

Note that N_{O2} is the amount of the released oxygen molecules. The amount of released oxygen in the case of being converted into oxygen atoms is twice the amount of the released oxygen molecules.

Furthermore, the insulator from which oxygen is released by heat treatment may contain a peroxide radical. Specifically, the spin density attributed to the peroxide radical is greater than or equal to 5×10¹⁷ spins/cm³. Note that the insulator containing a peroxide radical may have an asymmetric signal with a g factor of approximately 2.01 in ESR.

The insulator containing excess oxygen may be formed using oxygen-excess silicon oxide (SiO_{X} (X>2)). In the oxygen-excess silicon oxide (SiO_{X} (X>2)), the number of oxygen atoms per unit volume is more than twice the number of silicon atoms per unit volume. The number of silicon atoms and the number of oxygen atoms per unit volume are measured by Rutherford backscattering spectrometry (RBS).

As illustrated in FIG. 6B, the side surfaces of the semiconductor 406b are in contact with the layer 409a and the layer 409b. The semiconductor 406b can be electrically surrounded by an electric field of the conductor 404 (a transistor structure in which a semiconductor is electrically surrounded by an electric field of a conductor is referred to as a surrounded channel (s-channel) structure). Therefore, a channel is formed in the entire semiconductor 406b (bulk) in some cases. In the s-channel structure, a large amount of current can flow between a source and a drain of a transistor, so that a high on-state current can be obtained.

The s-channel structure is suitable for a miniaturized transistor because a high on-state current can be obtained. A semiconductor device including the miniaturized transistor can have a high integration degree and high density. For example, the channel length of the transistor is preferably less than or equal to 40 nm, more preferably less than or equal to 30 nm, still more preferably less than or equal to 20 nm in a region and the channel width of the transistor is preferably less than or equal to 40 nm, more preferably less than or equal to 30 nm, still more preferably less than or equal to 20 nm in a region.

Furthermore, by applying a lower voltage or a higher voltage than a source electrode to the conductor 413, the threshold voltage of the transistor may be shifted in the positive direction or the negative direction. For example, when the threshold voltage of the transistor is shifted in the positive direction, a normally-off transistor which is in a non-conduction state (off state) when the gate voltage is 0 V can be obtained in some cases. The voltage applied to the conductor 413 may be a variable or a fixed voltage. When a variable voltage is applied to the conductor 413, a circuit for controlling the voltage may be electrically connected to the conductor 413.

An oxide semiconductor which can be used as the semiconductor 406a, the semiconductor 406b, the semiconductor 406c, or the like is described below.

The semiconductor 406b is an oxide semiconductor containing indium, for example. The oxide semiconductor 406b can have high carrier mobility (electron mobility) by containing indium, for example. The semiconductor 406b preferably contains an element M. The element M is preferably aluminum, gallium, yttrium, tin, or the like. Other elements which can be used as the element M are boron, silicon, titanium, iron, nickel, germanium, yttrium, zirconium, molybdenum, lanthanum, cerium, neodymium, hafnium, tantalum, tungsten, and the like. Note that two or more of the above elements may be used in combination as the element M. The element M is an element having high bonding energy with oxygen, for example. The element M is an element whose bonding energy with oxygen is higher than that of indium. The element M is an element that can increase the energy gap of the oxide semiconductor, for example. Furthermore, the semiconductor 406b preferably contains zinc. When the oxide semiconductor contains zinc, the oxide semiconductor is easily crystallized, for example.

Note that the semiconductor 406b is not limited to the oxide semiconductor containing indium. The semiconductor 406b may be, for example, an oxide semiconductor which does not contain indium and contains zinc, an oxide semiconductor which does not contain indium and contains gallium, or an oxide semiconductor which does not contain indium and contains tin, e.g., a zinc tin oxide or a gallium tin oxide.

For the semiconductor 406b, an oxide with a wide energy gap may be used. For example, the energy gap of the semiconductor 406b is greater than or equal to 2.5 eV and less than or equal to 4.2 eV, preferably greater than or equal to 2.8 eV and less than or equal to 3.8 eV, more preferably greater than or equal to 3 eV and less than or equal to 3.5 eV.

For example, the semiconductor 406a and the semiconductor 406c are oxide semiconductors including one or more elements other than oxygen included in the semiconductor 406b. Since the semiconductor 406a and the semiconductor 406c each include one or more elements other than oxygen included in the semiconductor 406b, an interface state is less likely to be formed at the interface between the semiconductor 406a and the semiconductor 406b and the interface between the semiconductor 406b and the semiconductor 406c.

The semiconductor 406a, the semiconductor 406b, and the semiconductor 406c preferably include at least indium. In the case of using an In-M-Zn oxide as the semiconductor 406a, when a summation of In and M is assumed to be 100 atomic %, the proportions of In and M are preferably set to be less than 50 atomic % and greater than 50 atomic %, respectively, more preferably less than 25 atomic % and greater than 75 atomic %, respectively. In the case of using an In-M-Zn oxide as the semiconductor 406b, when a summation of In and M is assumed to be 100 atomic %, the proportions of In and M are preferably set to be greater than 25 atomic % and less than 75 atomic %, respectively, more preferably greater than 34 atomic % and less than 66 atomic %, respectively. In the case of using an In-M-Zn oxide as the semiconductor 406c, when a summation of In and M is assumed to be 100 atomic %, the proportions of In and M are preferably set to be less than 50 atomic % and greater than 50 atomic %, respectively, more preferably less than 25 atomic % and greater than 75 atomic %, respectively. Note that the semiconductor 406c may be an oxide that is a type the same as that of the semiconductor 406a. Note that the semiconductor 406a and/or the semiconductor 406c do/does not necessarily contain indium in some cases. For example, the semiconductor 406a and/or the semiconductor 406c may be gallium oxide.

As the semiconductor 406b, an oxide having an electron affinity higher than those of the semiconductors 406a and 406c is used. For example, as the semiconductor 406b, an oxide having an electron affinity higher than those of the semiconductors 406a and 406c by 0.07 eV or higher and 1.3 eV or lower, preferably 0.1 eV or higher and 0.7 eV or lower, more preferably 0.15 eV or higher and 0.4 eV or lower is used. Note that the electron affinity refers to an energy difference between the vacuum level and the bottom of the conduction band.

An indium gallium oxide has small electron affinity and a high oxygen-blocking property. Therefore, the semiconductor 406c preferably includes an indium gallium oxide. The gallium atomic ratio [Ga/(In+Ga)] is, for example, higher than or equal to 70%, preferably higher than or equal to 80%, more preferably higher than or equal to 90%.

At this time, when a gate voltage is applied, a channel is formed in the semiconductor 406b having the highest electron affinity in the semiconductor 406a, the semiconductor 406b, and the semiconductor 406c.

Here, in some cases, there is a mixed region of the semiconductor 406a and the semiconductor 406b between the semiconductor 406a and the semiconductor 406b.

Furthermore, in some cases, there is a mixed region of the semiconductor 406b and the semiconductor 406c between the semiconductor 406b and the semiconductor 406c. The mixed region has a low interface state density. For that reason, the stack including the semiconductor 406a, the semiconductor 406b, and the semiconductor 406c has a band structure where energy at each interface and in the vicinity of the interface is changed continuously (continuous junction).

At this time, electrons move mainly in the semiconductor 406b, not in the semiconductor 406a and the semiconductor 406c. As described above, when the interface state density at the interface between the semiconductor 406a and the semiconductor 406b and the interface state density at the interface between the semiconductor 406b and the semiconductor 406c are decreased, electron movement in the semiconductor 406b is less likely to be inhibited and the on-sate current of the transistor can be increased.

As factors of inhibiting electron movement are decreased, the on-state current of the transistor can be increased. For example, in the case where there is no factor of inhibiting electron movement, electrons are assumed to be efficiently moved. Electron movement is inhibited, for example, in the case where physical unevenness in the channel formation region is large.

To increase the on-state current of the transistor, for example, root mean square (RMS) roughness with a measurement area of 1 μm×1 μm of a top surface or a bottom surface of the semiconductor 406b (a formation surface; here, the semiconductor 406a) is less than 1 nm, preferably less than 0.6 nm, more preferably less than 0.5 nm, still more preferably less than 0.4 nm. The average surface roughness (also referred to as Ra) with the measurement area of 1 μm×1 μm is less than 1 nm, preferably less than 0.6 nm, more preferably less than 0.5 nm, still more preferably less than 0.4 nm. The maximum difference (P−V) with the measurement area of 1 μm×1 μm is less than 10 nm, preferably less than 9 nm, more preferably less than 8 nm, still more preferably less than 7 nm. RMS roughness, Ra, and P−V can be measured using a scanning probe microscope SPA-500 manufactured by SII Nano Technology Inc.

The electron movement is also inhibited, for example, in the case where the density of defect states is high in a region where a channel is formed.

For example, in the case were the semiconductor 406b contains oxygen vacancies (also denoted by V_{O}), donor levels are formed by entry of hydrogen into sites of oxygen vacancies in some cases. A state in which hydrogen enters sites of oxygen vacancies are denoted by V_{O}H in the following description in some cases. V_{O}H is a factor of decreasing the on-state current of the transistor because V_{O}H scatters electrons. Note that sites of oxygen vacancies become more stable by entry of oxygen than by entry of hydrogen. Thus, by decreasing oxygen vacancies in the semiconductor 406b, the on-state current of the transistor can be increased in some cases.

To decrease oxygen vacancies in the semiconductor 406b, for example, there is a method in which excess oxygen in the insulator 402 is moved to the semiconductor 406b through the semiconductor 406a. In this case, the semiconductor 406a is preferably a layer having an oxygen-transmitting property (a layer through which oxygen passes or is transmitted).

In the case where the transistor has an s-channel structure, a channel is formed in the whole of the semiconductor 406b. Therefore, as the semiconductor 406b has a larger thickness, a channel region becomes larger. In other words, the thicker the semiconductor 406b is, the larger the on-state current of the transistor is. For example, the semiconductor 406b has a region with a thickness of greater than or equal to 20 nm, preferably greater than or equal to 40 nm, more preferably greater than or equal to 60 nm, still more preferably greater than or equal to 100 nm Note that the semiconductor 406b has a region with a thickness of, for example, less than or equal to 300 nm, preferably less than or equal to 200 nm, more preferably less than or equal to 150 nm because the productivity of the semiconductor device might be decreased.

Moreover, the thickness of the semiconductor 406c is preferably as small as possible to increase the on-state current of the transistor. For example, the semiconductor 406c has a region with a thickness of less than 10 nm, preferably less than or equal to 5 nm, more preferably less than or equal to 3 nm Meanwhile, the semiconductor 406c has a function of blocking entry of elements other than oxygen (such as hydrogen and silicon) included in the adjacent insulator into the semiconductor 406b where a channel is formed. For this reason, it is preferable that the semiconductor 406c have a certain thickness. For example, the semiconductor 406c has a region with a thickness of greater than or equal to 0.3 nm, preferably greater than or equal to 1 nm, more preferably greater than or equal to 2 nm. The semiconductor 406c preferably has an oxygen blocking property to suppress outward diffusion of oxygen released from the insulator 402 and the like.

To improve reliability, preferably, the thickness of the semiconductor 406a is large and the thickness of the semiconductor 406c is small. For example, the semiconductor 406a has a region with a thickness of greater than or equal to 10 nm, preferably greater than or equal to 20 nm, more preferably greater than or equal to 40 nm, still more preferably greater than or equal to 60 nm. When the thickness of the semiconductor 406a is made large, a distance from an interface between the adjacent insulator and the semiconductor 406a to the semiconductor 406b in which a channel is formed can be large. Since the productivity of the semiconductor device might be decreased, the semiconductor 406a has a region with a thickness of, for example, less than or equal to 200 nm, preferably less than or equal to 120 nm, more preferably less than or equal to 80 nm.

For example, a region with a silicon concentration of lower than 1×10¹⁹ atoms/cm³, preferably lower than 5×10¹⁸ atoms/cm³, more preferably lower than 2×10¹⁸ atoms/cm³ which is measured by secondary ion mass spectrometry (SIMS) is provided between the semiconductor 406b and the semiconductor 406a. A region with a silicon concentration of lower than 1×10¹⁹ atoms/cm³, preferably lower than 5×10¹⁸ atoms/cm³, more preferably lower than 2×10¹⁸ atoms/cm³ which is measured by SIMS is provided between the semiconductor 406b and the semiconductor 406c.

The semiconductor 406b has a region in which the concentration of hydrogen measured by SIMS is lower than or equal to 2×10²⁰ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³. It is preferable to reduce the concentration of hydrogen in the semiconductor 406a and the semiconductor 406c in order to reduce the concentration of hydrogen in the semiconductor 406b. The semiconductor 406a and the semiconductor 406c each have a region in which the concentration of hydrogen measured by SIMS is lower than or equal to 2×10²⁰ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³. The semiconductor 406b has a region in which the concentration of nitrogen measured by SIMS is lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³. It is preferable to reduce the concentration of nitrogen in the semiconductor 406a and the semiconductor 406c in order to reduce the concentration of nitrogen in the semiconductor 406b. The semiconductor 406a and the semiconductor 406c each have a region in which the concentration of nitrogen measured by SIMS is lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The above three-layer structure is an example. For example, a two-layer structure without the semiconductor 406a or the semiconductor 406c may be employed. A four-layer structure in which any one of the semiconductors described as examples of the semiconductor 406a, the semiconductor 406b, and the semiconductor 406c is provided under or over the semiconductor 406a or under or over the semiconductor 406c may be employed. An n-layer structure (n is an integer of 5 or more) in which any one of the semiconductors described as examples of the semiconductor 406a, the semiconductor 406b, and the semiconductor 406c is provided at two or more of the following positions: over the semiconductor 406a, under the semiconductor 406a, over the semiconductor 406c, and under the semiconductor 406c.

As the substrate 400, an insulator substrate, a semiconductor substrate, or a conductor substrate may be used, for example. As the insulator substrate, a glass substrate, a quartz substrate, a sapphire substrate, a stabilized zirconia substrate (e.g., an yttria-stabilized zirconia substrate), or a resin substrate is used, for example. As the semiconductor substrate, a single material semiconductor substrate of silicon, germanium, or the like or a compound semiconductor substrate of silicon carbide, silicon germanium, gallium arsenide, indium phosphide, zinc oxide, gallium oxide, or the like is used, for example. A semiconductor substrate in which an insulator region is provided in the above semiconductor substrate, e.g., a silicon on insulator (SOI) substrate or the like is used. As the conductor substrate, a graphite substrate, a metal substrate, an alloy substrate, a conductive resin substrate, or the like is used. A substrate including a metal nitride, a substrate including a metal oxide, or the like is used. An insulator substrate provided with a conductor or a semiconductor, a semiconductor substrate provided with a conductor or an insulator, a conductor substrate provided with a semiconductor or an insulator, or the like is used. Alternatively, any of these substrates over which an element is provided may be used. As the element provided over the substrate, a capacitor, a resistor, a switching element, a light-emitting element, a memory element, or the like is used.

Alternatively, a flexible substrate may be used as the substrate 400. As a method for providing a transistor over a flexible substrate, there is a method in which the transistor is formed over a non-flexible substrate and then the transistor is separated and transferred to the substrate 400 which is a flexible substrate. In that case, a separation layer is preferably provided between the non-flexible substrate and the transistor. As the substrate 400, a sheet, a film, or a foil containing a fiber may be used. The substrate 400 may have elasticity. The substrate 400 may have a property of returning to its original shape when bending or pulling is stopped. Alternatively, the substrate 400 may have a property of not returning to its original shape. The thickness of the substrate 400 is, for example, greater than or equal to 5 μm and less than or equal to 700 μm, preferably greater than or equal to 10 μm and less than or equal to 500 μm, more preferably greater than or equal to 15 μm and less than or equal to 300 μm. When the substrate 400 has a small thickness, the weight of the semiconductor device can be reduced. When the substrate 400 has a small thickness, even in the case of using glass or the like, the substrate 400 may have elasticity or a property of returning to its original shape when bending or pulling is stopped. Therefore, an impact applied to the semiconductor device over the substrate 400, which is caused by dropping or the like, can be reduced. That is, a durable semiconductor device can be provided.

For the substrate 400 which is a flexible substrate, metal, an alloy, resin, glass, or fiber thereof can be used, for example. The flexible substrate 400 preferably has a lower coefficient of linear expansion because deformation due to an environment is suppressed. The flexible substrate 400 is formed using, for example, a material whose coefficient of linear expansion is lower than or equal to 1×10⁻³/K, lower than or equal to 5×10⁻⁵/K, or lower than or equal to 1×10⁻⁵/K. Examples of the resin include polyester, polyolefin, polyamide (e.g., nylon or aramid), polyimide, polycarbonate, and acrylic. In particular, aramid is preferably used for the flexible substrate 400 because of its low coefficient of linear expansion.

The conductor 413 may be formed to have a single-layer structure or a stacked-layer structure using a conductor containing one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten, for example. An alloy or a compound containing the above element may be used, for example, and a conductor containing aluminum, a conductor containing copper and titanium, a conductor containing copper and manganese, a conductor containing indium, tin, and oxygen, a conductor containing titanium and nitrogen, or the like may be used.

The insulator 402 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 402 may be formed using aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

The insulator 402 may have a function of preventing diffusion of impurities from the substrate 400. In the case where the semiconductor 406b is an oxide semiconductor, the insulator 402 can have a function of supplying oxygen to the semiconductor 406b.

The layers 409a and 409b may be formed using a transparent conductor, an oxide semiconductor, a nitride semiconductor, or an oxynitride semiconductor, for example. The layers 409a and 409b may be formed using, for example, a layer containing indium, tin, and oxygen, a layer containing indium and zinc, a layer containing indium, tungsten, and zinc, a layer containing tin and zinc, a layer containing zinc and gallium, a layer containing zinc and aluminum, a layer containing zinc and fluorine, a layer containing zinc and boron, a layer containing tin and antimony, a layer containing tin and fluorine, a layer containing titanium and niobium, or the like. Alternatively, any of these layers may contain hydrogen, carbon, nitrogen, silicon, germanium, or argon.

The layers 409a and 409b may have a property of transmitting visible light. Alternatively, the layers 409a and 409b may have a property of not transmitting visible light, ultraviolet light, infrared light, or X-rays by reflecting or absorbing it. In some cases, such a property can suppress a change in electrical characteristics of the transistor due to stray light.

The layers 409a and 409b may preferably be formed using a layer which does not form a Schottky barrier with the semiconductor 406b or the like. Accordingly, on-state characteristics of the transistor can be improved.

Each of the conductor 416a and the conductor 416b may be formed to have, for example, a single-layer structure or a stacked-layer structure including a conductor containing one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy or a compound containing the above element may be used, for example, and a conductor containing aluminum, a conductor containing copper and titanium, a conductor containing copper and manganese, a conductor containing indium, tin, and oxygen, a conductor containing titanium and nitrogen, or the like may be used.

Note that the layers 409a and 409b may preferably be formed using a layer having a resistance higher than that of the conductors 416a and 416b. The layers 409a and 409b may preferably be formed using a layer having a resistance lower than that of the channel of the transistor. For example, the layers 409a and 409b may have a resistivity higher than or equal to 0.1 Ωcm and lower than or equal to 100 Ωcm, higher than or equal to 0.5 Ωcm and lower than or equal to 50 Ωcm, or higher than or equal to 1 Ωcm and lower than or equal to 10 Ωcm. The layers 409a and 409b having a resistivity within the above range can reduce electric field concentration in a boundary portion between the channel and the drain. Therefore, a change in electrical characteristics of the transistor can be suppressed. In addition, a punch-through current generated by an electric field from the drain can be reduced. Thus, a transistor with a small channel length can have favorable saturation characteristics. Note that in a circuit configuration where the source and the drain do not interchange, only one of the layers 409a and 409b (e.g., the layer on the drain side) may preferably be provided.

The insulator 412 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 412 may be formed using aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

The conductor 404 may be formed to have, for example, a single-layer structure or a stacked-layer structure including a conductor containing one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy or a compound containing the above element may be used, for example, and a conductor containing aluminum, a conductor containing copper and titanium, a conductor containing copper and manganese, a conductor containing indium, tin, and oxygen, a conductor containing titanium and nitrogen, or the like may be used.

The insulator 408 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 408 may be preferably formed to have, for example, a single-layer structure or a stacked-layer structure including an insulator containing aluminum oxide, silicon nitride oxide, silicon nitride, gallium oxide, yttrium oxide, zirconium oxide, lanthanum oxide, neodymium oxide, hafnium oxide, or tantalum oxide.

The insulator 418 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 418 may be formed using aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

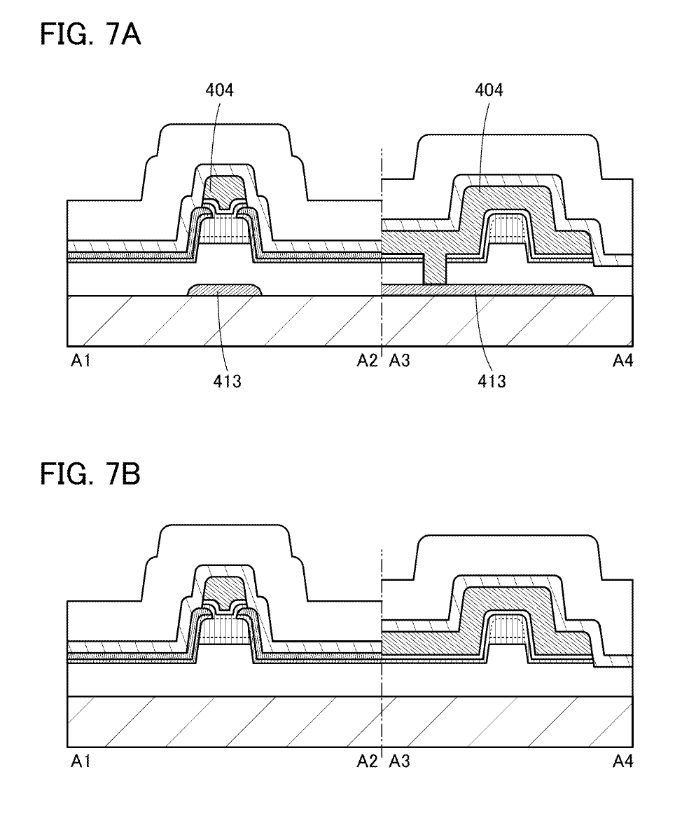

Although FIGS. 6A and 6B show an example where the conductor 404 which is a first gate electrode of a transistor is not electrically connected to the conductor 413 which is a second gate electrode, a transistor structure of one embodiment of the present invention is not limited thereto. For example, as illustrated in FIG. 7A, the conductor 404 may be electrically connected to the conductor 413. With such a structure, the conductor 404 and the conductor 413 are supplied with the same potential; thus, switching characteristics of the transistor can be improved. Alternatively, as illustrated in FIG. 7B, the conductor 413 is not necessarily provided.

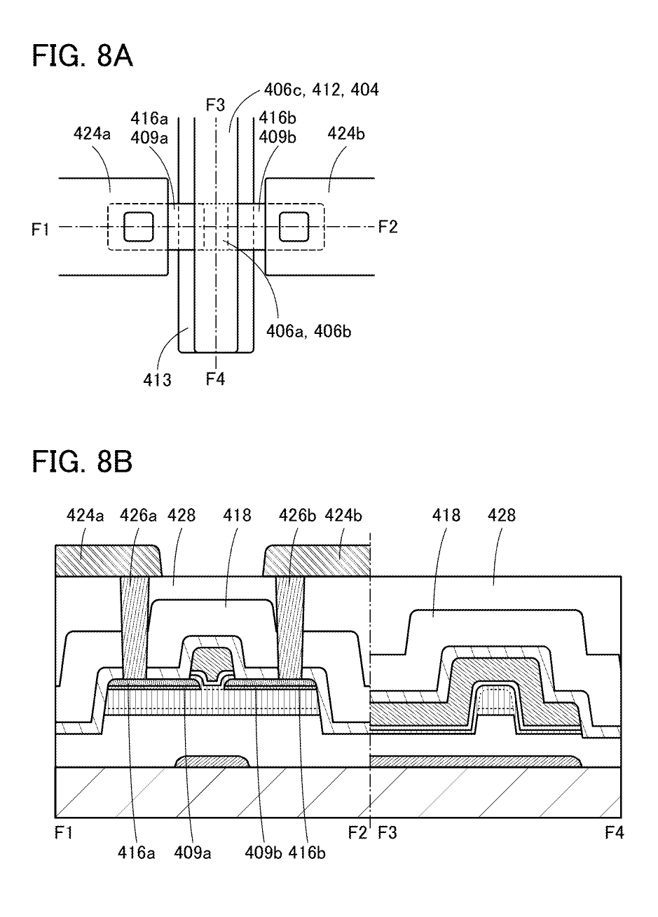

FIG. 8A is an example of a top view of a transistor. FIG. 8B is an example of a cross-sectional view taken along dashed-dotted line F1-F2 and dashed-dotted line F3-F4 in FIG. 8A. Note that some components such as an insulator are omitted in FIG. 8A for easy understanding.

FIGS. 6A and 6B and the like show an example where the conductor 416a and the conductor 416b which function as a source electrode and a drain electrode are in contact with a top surface and a side surface of the semiconductor 406b, a top surface of the insulator 402, and the like with the layer 409a and the layer 409b provided therebetween; however, a structure of a transistor one embodiment of the present invention is not limited thereto. For example, as illustrated in FIGS. 8A and 8B, the conductor 416a and the conductor 416b may be in contact with only the top surface of the semiconductor 406b with the layer 409a and the layer 409b provided therebetween.

As illustrated in FIG. 8B, an insulator 428 may be provided over the insulator 418. The insulator 428 preferably has a flat top surface. The insulator 428 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 428 may be formed using aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide. To planarize the top surface of the insulator 428, planarization treatment may be performed by a chemical mechanical polishing (CMP) method or the like.

A resin may be used as the insulator 428. For example, a resin containing polyimide, polyamide, acrylic, silicone, or the like may be used. The use of a resin does not need planarization treatment performed on the top surface of the insulator 428 in some cases. By using a resin, a thick film can be formed in a short time; thus, the productivity can be increased.

As illustrated in FIGS. 8A and 8B a conductor 424a and a conductor 424b may be provided over the insulator 428. The conductor 424a and the conductor 424b may function as wirings, for example. The insulator 428 may include an opening and the conductor 416a and the conductor 424a may be electrically connected to each other through the opening. The insulator 428 may have another opening and the conductor 416b and the conductor 424b may be electrically connected to each other through the opening. In this case, the conductor 426a and the conductor 426b may be provided in the respective openings.

Each of the conductor 424a and the conductor 424b may be formed to have, for example, a single-layer structure or a stacked-layer structure including a conductor containing one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy or a compound containing the above element may be used, for example, and a conductor containing aluminum, a conductor containing copper and titanium, a conductor containing copper and manganese, a conductor containing indium, tin, and oxygen, a conductor containing titanium and nitrogen, or the like may be used.

In the transistor illustrated in FIGS. 8A and 8B, the layer 409a and the layer 409b are not in contact with side surfaces of the semiconductor 406b. Thus, an electric field applied from the conductor 404 functioning as a first gate electrode to the side surfaces of the semiconductor 406b is less likely to be blocked by the layer 409a, the layer 409b, and the like. The layer 409a and the layer 409b are not in contact with a top surface of the insulator 402. Thus, excess oxygen (oxygen) released from the insulator 402 is not consumed to oxidize the layer 409a and the layer 409b. Accordingly, excess oxygen (oxygen) released from the insulator 402 can be efficiently used to reduce oxygen vacancies in the semiconductor 406b. In other words, the transistor having the structure illustrated in FIGS. 8A and 8B has excellent electrical characteristics such as a high on-state current, high field-effect mobility, a small subthreshold swing value, and high reliability.

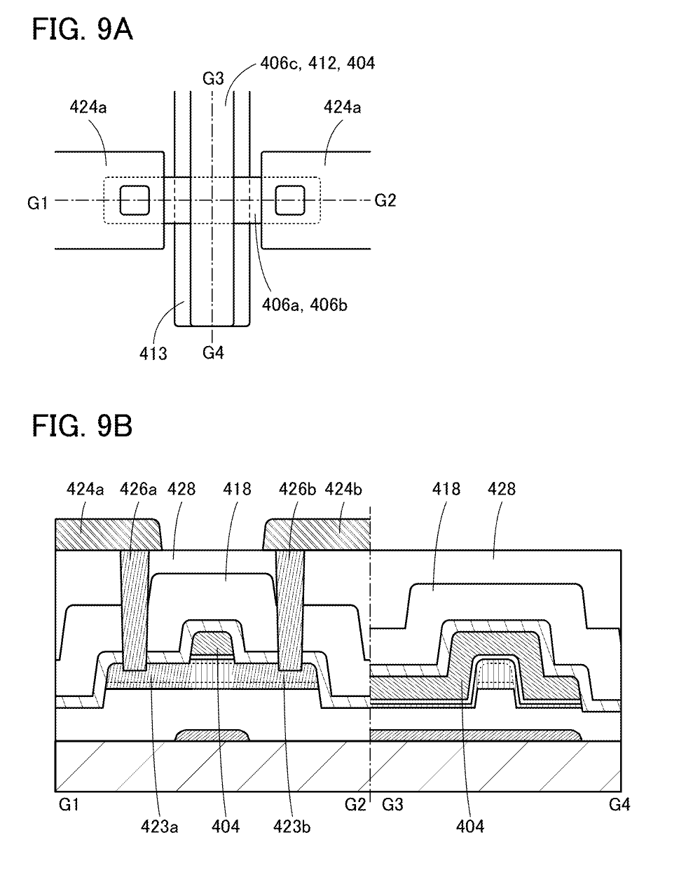

FIGS. 9A and 9B are a top view and a cross-sectional view of a transistor of one embodiment of the present invention. FIG. 9A is a top view and FIG. 9B is a cross-sectional view taken along dashed-dotted line G1-G2 and dashed-dotted line G3-G4 in FIG. 9A. Note that for simplification of the drawing, some components are not illustrated in the top view in FIG. 9A.

The transistor may have a structure in which, as illustrated in FIGS. 9A and 9B, the layer 409a, the layer 409b, the conductor 416a, and the conductor 416b are not provided and the conductor 426a and the conductor 426b are in contact with the semiconductor 406b. In this case, the low-resistance region 423a (low-resistance region 423b) is preferably provided in a region in contact with at least the conductor 426a and the conductor 426b in the semiconductor 406b and/or the semiconductor 406a. The low-resistance region 423a and the low-resistance region 423b may be formed in such a manner that, for example, the conductor 404 and the like are used as masks and impurities are added to the semiconductor 406b and/or the semiconductor 406a. The conductor 426a and the conductor 426b may be provided in holes (portions which penetrate) or recessed portions (portions which do not penetrate) of the semiconductor 406b. When the conductor 426a and the conductor 426b are provided in holes or recessed portions of the semiconductor 406b, contact areas between the conductors 426a and 426b and the semiconductor 406b are increased; thus, the adverse effect of the contact resistance can be decreased. In other words, the on-state current of the transistor can be increased.

### <Transistor Structure 2>

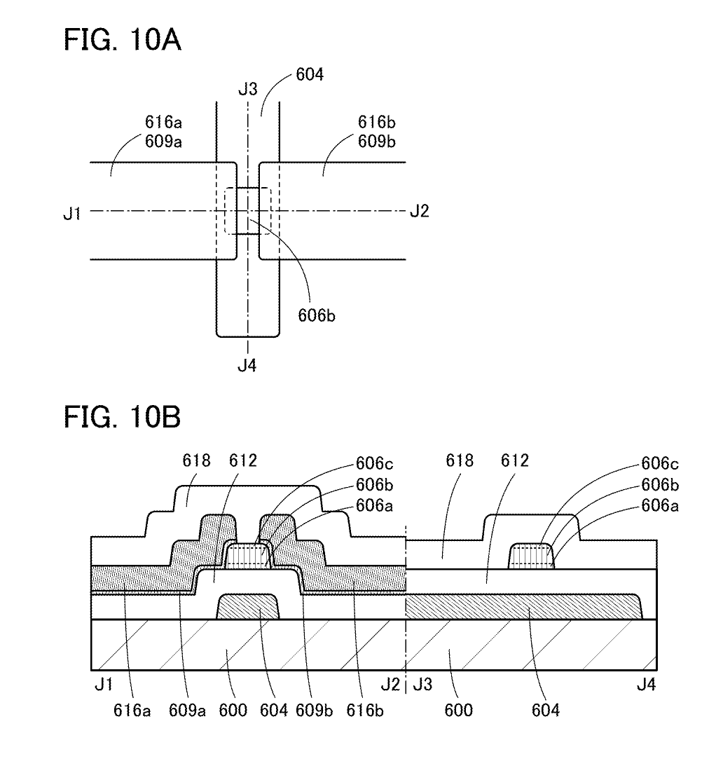

FIGS. 10A and 10B are a top view and a cross-sectional view which illustrate a transistor of one embodiment of the present invention. FIG. 10A is a top view and FIG. 10B is a cross-sectional view taken along dashed-dotted line J1-J2 and dashed-dotted line J3-J4 in FIG. 10A. Note that for simplification of the drawing, some components are not illustrated in the top view in FIG. 10A.

The transistor in FIGS. 10A and 10B includes a conductor 604 over a substrate 600, an insulator 612 over the conductor 604, a semiconductor 606a over the insulator 612, a semiconductor 606b over the semiconductor 606a, a semiconductor 606c over the semiconductor 606b, a layer 609a and a layer 609b which are in contact with the semiconductor 606a, the semiconductor 606b, and the semiconductor 606c and which are arranged to be apart from each other, a conductor 616a over the layer 609a, a conductor 616b over the layer 609b, and an insulator 618 over the semiconductor 606c, the conductor 616a, and the conductor 616b. The conductor 604 faces a bottom surface of the semiconductor 606b with the insulator 612 provided therebetween. The insulator 612 may have a projection. An insulator may be provided between the substrate 600 and the conductor 604. For the insulator, the description of the insulator 402 or the insulator 408 is referred to. The semiconductor 606a, the insulator 618, the layer 609a, and/or the layer 609b are/is not necessarily provided.

The semiconductor 606b serves as a channel formation region of the transistor. The conductor 604 serves as a first gate electrode (also referred to as a front gate electrode) of the transistor. The conductor 616a and the conductor 616b serve as a source electrode and a drain electrode of the transistor.

The insulator 618 is preferably an insulator containing excess oxygen.

For the substrate 600, the description of the substrate 400 is referred to. For the conductor 604, the description of the conductor 404 is referred to. For the insulator 612, the description of the insulator 412 is referred to. For the semiconductor 606a, the description of the semiconductor 406c is referred to. For the semiconductor 606b, the description of the semiconductor 406b is referred to. For the semiconductor 606c, the description of the semiconductor 406a is referred to. For the layer 609a and the layer 609b, the description of the layer 409a and the layer 409b is referred to. For the conductor 616a and the conductor 616b, the description of the conductor 416a and the conductor 416b is referred to. For the insulator 618, the description of the insulator 402 is referred to.

Over the insulator 618, a display element may be provided. For example, a pixel electrode, a liquid crystal layer, a common electrode, a light-emitting layer, an organic EL layer, an anode electrode, a cathode electrode, or the like may be provided. The display element is connected to the conductor 616a or the like, for example.

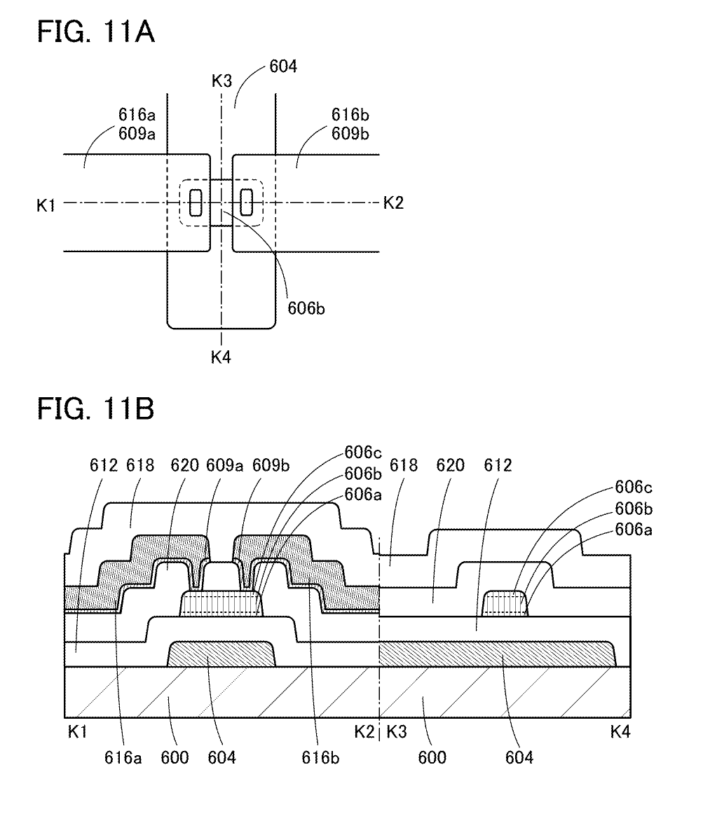

FIG. 11A is an example of a top view of a transistor. FIG. 11B is an example of a cross-sectional view taken along dashed-dotted line K1-K2 and dashed-dotted line K3-K4 in FIG. 11A. Note that some components such as an insulator are omitted in FIG. 11A for easy understanding.

Over the semiconductor, an insulator that can function as a channel protective film may be provided. For example, as illustrated in FIGS. 11A and 11B, an insulator 620 may be provided between the semiconductor 606c and the layers 609a and 609b. In that case, the layer 609a (the layer 609b) and the semiconductor 606c are connected to each other through an opening in the insulator 620. For the insulator 620, the description of the insulator 618 may be referred to.

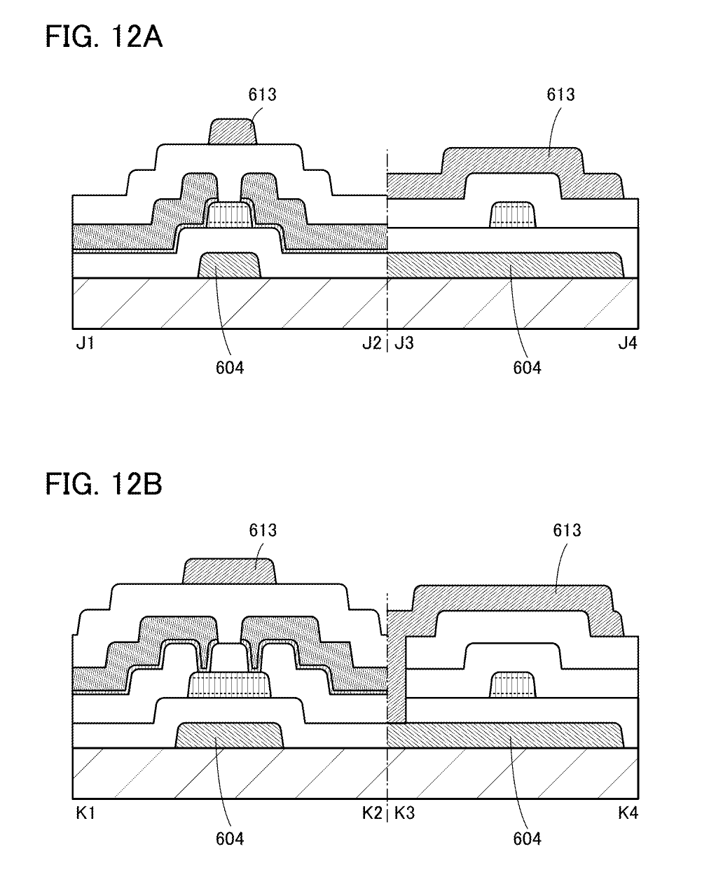

In FIG. 10B and FIG. 11B, a conductor 613 may be provided over the insulator 618. Examples in that case are shown in FIGS. 12A and 12B. For the conductor 613, the description of the conductor 413 is referred to. A potential or signal which is the same as that supplied to the conductor 604 or a potential or signal which is different from that supplied to the conductor 604 may be supplied to the conductor 613. For example, by supplying a constant potential to the conductor 613, the threshold voltage of a transistor may be controlled. In other words, the conductor 613 can function as a second gate electrode. Note that the transistor may have an s-channel structure using the conductor 613 or the like.

### <Semiconductor Device>

An example of a semiconductor device of one embodiment of the present invention is shown below.

### <Circuit>

An example of a circuit including a transistor of one embodiment of the present invention is shown below.

### [CMOS Inverter]

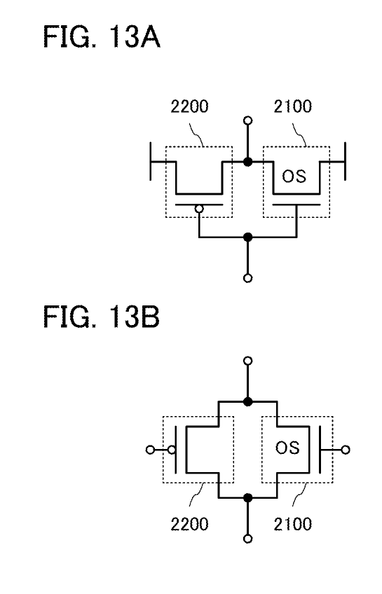

A circuit diagram in FIG. 13A shows a configuration of a so-called CMOS inverter in which the p-channel transistor 2200 and the n-channel transistor 2100 are connected to each other in series and in which gates of them are connected to each other.

### [CMOS Analog Switch]

A circuit diagram in FIG. 13B shows a configuration in which sources of the transistors 2100 and 2200 are connected to each other and drains of the transistors 2100 and 2200 are connected to each other. With such a configuration, the transistors can function as a so-called CMOS analog switch.

### [Memory Device Example]

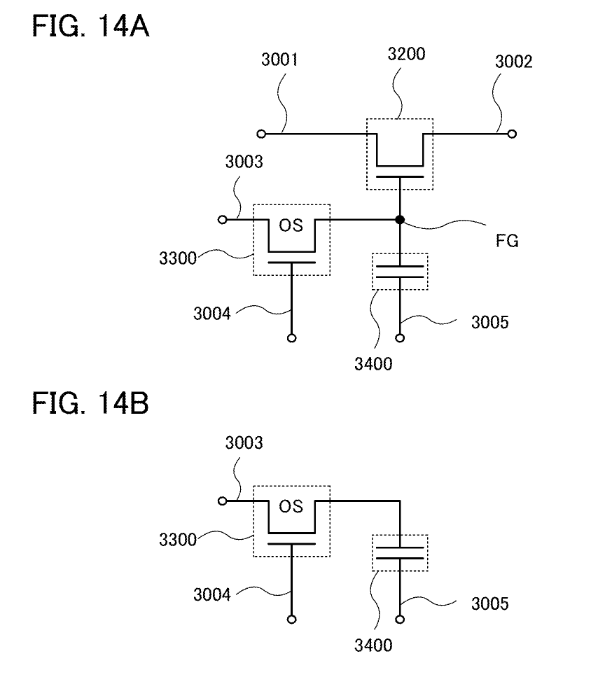

An example of a semiconductor device (memory device) which includes the transistor of one embodiment of the present invention, which can retain stored data even when not powered, and which has an unlimited number of write cycles is shown in FIGS. 14A and 14B.

The semiconductor device illustrated in FIG. 14A includes a transistor 3200 using a first semiconductor, a transistor 3300 using a second semiconductor, and a capacitor 3400. Note that any of the above-described transistors can be used as the transistor 3300.

The transistor 3300 is a transistor using an oxide semiconductor. Since the off-state current of the transistor 3300 is low, stored data can be retained for a long period at a predetermined node of the semiconductor device. In other words, power consumption of the semiconductor device can be reduced because refresh operation becomes unnecessary or the frequency of refresh operation can be extremely low.

In FIG. 14A, a first wiring 3001 is electrically connected to a source of the transistor 3200. A second wiring 3002 is electrically connected to a drain of the transistor 3200. A third wiring 3003 is electrically connected to one of the source and the drain of the transistor 3300. A fourth wiring 3004 is electrically connected to the gate of the transistor 3300. The gate of the transistor 3200 and the other of the source and the drain of the transistor 3300 are electrically connected to the one electrode of the capacitor 3400. A fifth wiring 3005 is electrically connected to the other electrode of the capacitor 3400.

The semiconductor device in FIG. 14A has a feature that the potential of the gate of the transistor 3200 can be retained, and thus enables writing, retaining, and reading of data as follows.

Writing and retaining of data are described. First, the potential of the fourth wiring 3004 is set to a potential at which the transistor 3300 is turned on, so that the transistor 3300 is turned on. Accordingly, the potential of the third wiring 3003 is supplied to a node FG where the gate of the transistor 3200 and the one electrode of the capacitor 3400 are electrically connected to each other. That is, a predetermined charge is supplied to the gate of the transistor 3200 (writing). Here, one of two kinds of charges providing different potential levels (hereinafter referred to as a low-level charge and a high-level charge) is supplied. After that, the potential of the fourth wiring 3004 is set to a potential at which the transistor 3300 is turned off, so that the transistor 3300 is turned off. Thus, the charge is held at the node FG (retaining).

Since the off-state current of the transistor 3300 is extremely low, the charge of the node FG is retained for a long time.

Next, reading of data is described. An appropriate potential (a reading potential) is supplied to the fifth wiring 3005 while a predetermined potential (a constant potential) is supplied to the first wiring 3001, whereby the potential of the second wiring 3002 varies depending on the amount of charge retained in the node FG. This is because in the case of using an n-channel transistor as the transistor 3200, an apparent threshold voltage Vₜₕ_{_{—}}_{H} at the time when the high-level charge is given to the gate of the transistor 3200 is lower than an apparent threshold voltage Vₜₕ_{_{—}}_{L} at the time when the low-level charge is given to the gate of the transistor 3200. Here, an apparent threshold voltage refers to the potential of the fifth wiring 3005 which is needed to turn on the transistor 3200. Thus, the potential of the fifth wiring 3005 is set to a potential V₀ which is between Vₜₕ_{_{—}}_{H} and Vₜₕ_{_{—}}_{L}, whereby charge supplied to the node FG can be determined. For example, in the case where the high-level charge is supplied to the node FG in writing and the potential of the fifth wiring 3005 is V₀ (>Vₜₕ_{_{—}}_{H}), the transistor 3200 is turned on. On the other hand, in the case where the low-level charge is supplied to the node FG in writing, even when the potential of the fifth wiring 3005 is V₀ (<Vₜₕ_{_{—}}_{L}), the transistor 3200 remains off. Thus, the data retained in the node FG can be read by determining the potential of the second wiring 3002.

Note that in the case where memory cells are arrayed, it is necessary that data of a desired memory cell is read in read operation. In the case where data of the other memory cells is not read, the fifth wiring 3005 may be supplied with a potential at which the transistor 3200 is turned off regardless of the charge supplied to the node FG, that is, a potential lower than Vₜₕ_{_{—}}_{H}. Alternatively, the fifth wiring 3005 may be supplied with a potential at which the transistor 3200 is turned on regardless of the charge supplied to the node FG, that is, a potential higher than Vₜₕ_{_{—}}_{L}.

The semiconductor device in FIG. 14B is different form the semiconductor device in FIG. 14A in that the transistor 3200 is not provided. Also in this case, writing and retaining operation of data can be performed in a manner similar to that of the semiconductor device in FIG. 14A.

Reading of data in the semiconductor device in FIG. 14B is described. When the transistor 3300 is turned on, the third wiring 3003 which is in a floating state and the capacitor 3400 are electrically connected to each other, and the charge is redistributed between the third wiring 3003 and the capacitor 3400. As a result, the potential of the third wiring 3003 is changed. The amount of change in potential of the third wiring 3003 varies depending on the potential of the one electrode of the capacitor 3400 (or the charge accumulated in the capacitor 3400).

For example, the potential of the third wiring 3003 after the charge redistribution is (C_{B}×V_{B0}+C×V)/(C_{B}+C), where V is the potential of the one electrode of the capacitor 3400, C is the capacitance of the capacitor 3400, C_{B} is the capacitance component of the third wiring 3003, and V_{B0} is the potential of the third wiring 3003 before the charge redistribution. Thus, it can be found that, assuming that the memory cell is in either of two states in which the potential of the one electrode of the capacitor 3400 is V₁ and V₀ (V₁>V₀), the potential of the third wiring 3003 in the case of retaining the potential V₁ (=(C_{B}×V_{B0}+C×V₁)/(C_{B}+C)) is higher than the potential of the third wiring 3003 in the case of retaining the potential V₀ (=(C_{B}×V_{B0}+C×V₀)/(C_{B}+C)).

Then, by comparing the potential of the third wiring 3003 with a predetermined potential, data can be read.

In this case, a transistor including the first semiconductor may be used for a driver circuit for driving a memory cell, and a transistor including the second semiconductor may be stacked over the driver circuit as the transistor 3300.

When including a transistor using an oxide semiconductor and having an extremely low off-state current, the semiconductor device described above can retain stored data for a long time. In other words, power consumption of the semiconductor device can be reduced because refresh operation becomes unnecessary or the frequency of refresh operation can be extremely low. Moreover, stored data can be retained for a long time even when power is not supplied (note that a potential is preferably fixed).

In the semiconductor device, high voltage is not needed for writing data and deterioration of elements is less likely to occur. Unlike in a conventional nonvolatile memory, for example, it is not necessary to inject and extract electrons into and from a floating gate; thus, a problem such as deterioration of an insulator is not caused. That is, the semiconductor device of one embodiment of the present invention does not have a limit on the number of times data can be rewritten, which is a problem of a conventional nonvolatile memory, and the reliability thereof is drastically improved. Furthermore, data is written depending on the state of the transistor (on or off), whereby high-speed operation can be achieved.

### <CPU>

A CPU including a semiconductor device such as any of the above-described transistors or the above-described memory device is described below.

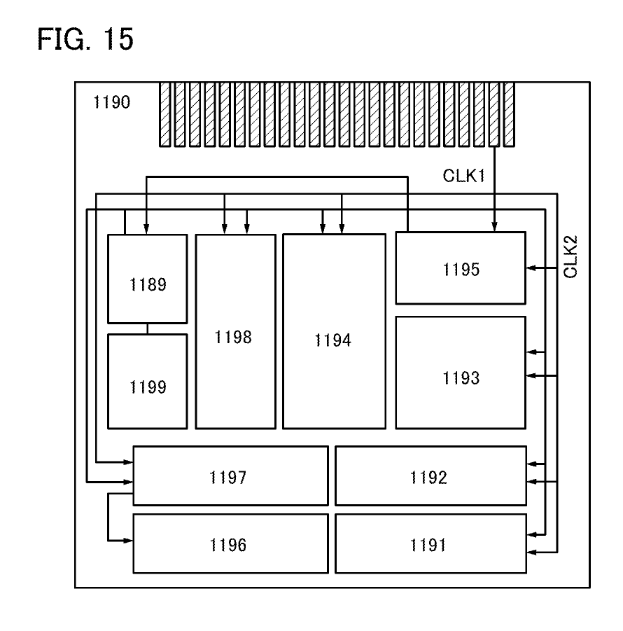

FIG. 15 is a block diagram illustrating a configuration example of a CPU including any of the above-described transistors as a component.

The CPU illustrated in FIG. 15 includes, over a substrate 1190, an arithmetic logic unit (ALU) 1191, an ALU controller 1192, an instruction decoder 1193, an interrupt controller 1194, a timing controller 1195, a register 1196, a register controller 1197, a bus interface 1198, a rewritable ROM 1199, and a ROM interface 1189. A semiconductor substrate, an SOI substrate, a glass substrate, or the like is used as the substrate 1190. The ROM 1199 and the ROM interface 1189 may be provided over a separate chip. Needless to say, the CPU in FIG. 15 is just an example in which the configuration has been simplified, and an actual CPU may have a variety of configurations depending on the application. For example, the CPU may have the following configuration: a structure including the CPU illustrated in FIG. 15 or an arithmetic circuit is considered as one core; a plurality of the cores are included; and the cores operate in parallel. The number of bits that the CPU can process in an internal arithmetic circuit or in a data bus can be 8, 16, 32, or 64, for example.

An instruction that is input to the CPU through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 judges an interrupt request from an external input/output device or a peripheral circuit on the basis of its priority or a mask state, and processes the request. The register controller 1197 generates an address of the register 1196, and reads/writes data from/to the register 1196 in accordance with the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal CLK2 based on a reference clock signal CLK1, and supplies the internal clock signal CLK2 to the above circuits.

In the CPU illustrated in FIG. 15, a memory cell is provided in the register 1196. For the memory cell of the register 1196, any of the above-described transistors, the above-described memory device, or the like can be used.

In the CPU illustrated in FIG. 15, the register controller 1197 selects operation of retaining data in the register 1196 in accordance with an instruction from the ALU 1191. That is, the register controller 1197 selects whether data is retained by a flip-flop or by a capacitor in the memory cell included in the register 1196. When data retaining by the flip-flop is selected, a power supply voltage is supplied to the memory cell in the register 1196. When data retaining by the capacitor is selected, the data is rewritten in the capacitor, and supply of power supply voltage to the memory cell in the register 1196 can be stopped.

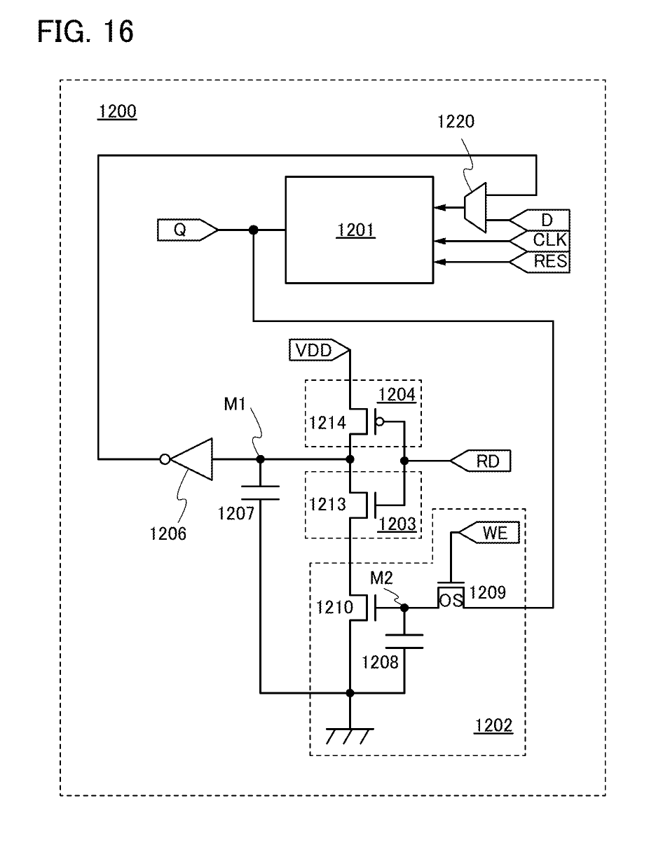

FIG. 16 is an example of a circuit diagram of a memory element 1200 that can be used as the register 1196. The memory element 1200 includes a circuit 1201 in which stored data is volatile when power supply is stopped, a circuit 1202 in which stored data is nonvolatile even when power supply is stopped, a switch 1203, a switch 1204, a logic element 1206, a capacitor 1207, and a circuit 1220 having a selecting function. The circuit 1202 includes a capacitor 1208, a transistor 1209, and a transistor 1210. Note that the memory element 1200 may further include another element such as a diode, a resistor, or an inductor, as needed.

Here, the above-described memory device can be used as the circuit 1202. When supply of a power supply voltage to the memory element 1200 is stopped, GND (0 V) or a potential at which the transistor 1209 in the circuit 1202 is turned off continues to be input to a gate of the transistor 1209. For example, the gate of the transistor 1209 is grounded through a load such as a resistor.

Shown here is an example in which the switch 1203 is a transistor 1213 having one conductivity type (e.g., an n-channel transistor) and the switch 1204 is a transistor 1214 having a conductivity type opposite to the one conductivity type (e.g., a p-channel transistor). A first terminal of the switch 1203 corresponds to one of a source and a drain of the transistor 1213, a second terminal of the switch 1203 corresponds to the other of the source and the drain of the transistor 1213, and conduction or non-conduction between the first terminal and the second terminal of the switch 1203 (i.e., the on/off state of the transistor 1213) is selected by a control signal RD input to a gate of the transistor 1213. A first terminal of the switch 1204 corresponds to one of a source and a drain of the transistor 1214, a second terminal of the switch 1204 corresponds to the other of the source and the drain of the transistor 1214, and conduction or non-conduction between the first terminal and the second terminal of the switch 1204 (i.e., the on/off state of the transistor 1214) is selected by the control signal RD input to a gate of the transistor 1214.

One of a source and a drain of the transistor 1209 is electrically connected to one of a pair of electrodes of the capacitor 1208 and a gate of the transistor 1210. Here, the connection portion is referred to as a node M2. One of a source and a drain of the transistor 1210 is electrically connected to a line which can supply a low power supply potential (e.g., a GND line), and the other thereof is electrically connected to the first terminal of the switch 1203 (the one of the source and the drain of the transistor 1213). The second terminal of the switch 1203 (the other of the source and the drain of the transistor 1213) is electrically connected to the first terminal of the switch 1204 (the one of the source and the drain of the transistor 1214). The second terminal of the switch 1204 (the other of the source and the drain of the transistor 1214) is electrically connected to a line which can supply a power supply potential VDD. The second terminal of the switch 1203 (the other of the source and the drain of the transistor 1213), the first terminal of the switch 1204 (the one of the source and the drain of the transistor 1214), an input terminal of the logic element 1206, and one of a pair of electrodes of the capacitor 1207 are electrically connected to each other. Here, the connection portion is referred to as a node M1. The other of the pair of electrodes of the capacitor 1207 can be supplied with a constant potential. For example, the other of the pair of electrodes of the capacitor 1207 can be supplied with a low power supply potential (e.g., GND) or a high power supply potential (e.g., VDD). The other of the pair of electrodes of the capacitor 1207 is electrically connected to the line which can supply a low power supply potential (e.g., a GND line). The other of the pair of electrodes of the capacitor 1208 can be supplied with a constant potential. For example, the other of the pair of electrodes of the capacitor 1208 can be supplied with the low power supply potential (e.g., GND) or the high power supply potential (e.g., VDD). The other of the pair of electrodes of the capacitor 1208 is electrically connected to the line which can supply a low power supply potential (e.g., a GND line).

The capacitor 1207 and the capacitor 1208 are not necessarily provided as long as the parasitic capacitance of the transistor, the wiring, or the like is actively utilized.

A control signal WE is input to the gate of the transistor 1209. As for each of the switch 1203 and the switch 1204, a conduction state or a non-conduction state between the first terminal and the second terminal is selected by the control signal RD which is different from the control signal WE. When the first terminal and the second terminal of one of the switches are in the conduction state, the first terminal and the second terminal of the other of the switches are in the non-conduction state.

A signal corresponding to data retained in the circuit 1201 is input to the other of the source and the drain of the transistor 1209. FIG. 16 illustrates an example in which a signal output from the circuit 1201 is input to the other of the source and the drain of the transistor 1209. The logic value of a signal output from the second terminal of the switch 1203 (the other of the source and the drain of the transistor 1213) is inverted by the logic element 1206, and the inverted signal is input to the circuit 1201 through the circuit 1220.

In the example of FIG. 16, a signal output from the second terminal of the switch 1203 (the other of the source and the drain of the transistor 1213) is input to the circuit 1201 through the logic element 1206 and the circuit 1220; however, one embodiment of the present invention is not limited thereto. The signal output from the second terminal of the switch 1203 (the other of the source and the drain of the transistor 1213) may be input to the circuit 1201 without its logic value being inverted. For example, in the case where the circuit 1201 includes a node in which a signal obtained by inversion of the logic value of a signal input from the input terminal is retained, the signal output from the second terminal of the switch 1203 (the other of the source and the drain of the transistor 1213) can be input to the node.

In FIG. 16, the transistors included in the memory element 1200 except for the transistor 1209 can each be a transistor in which a channel is formed in a film formed using a semiconductor other than an oxide semiconductor or in the substrate 1190. For example, the transistor can be a transistor whose channel is formed in a silicon film or a silicon substrate. Alternatively, all the transistors in the memory element 1200 may be a transistor in which a channel is formed in an oxide semiconductor. Further alternatively, in the memory element 1200, a transistor in which a channel is formed in an oxide semiconductor may be included besides the transistor 1209, and a transistor in which a channel is formed in a layer formed using a semiconductor other than an oxide semiconductor or in the substrate 1190 can be used for the rest of the transistors.

As the circuit 1201 in FIG. 16, for example, a flip-flop circuit can be used. As the logic element 1206, for example, an inverter or a clocked inverter can be used.

In a period during which the memory element 1200 is not supplied with the power supply voltage, the semiconductor device of one embodiment of the present invention can retain data stored in the circuit 1201 by the capacitor 1208 which is provided in the circuit 1202.

The off-state current of a transistor in which a channel is formed in an oxide semiconductor is extremely low. For example, the off-state current of a transistor in which a channel is formed in an oxide semiconductor is significantly lower than that of a transistor in which a channel is formed in silicon having crystallinity. Thus, when the transistor is used as the transistor 1209, a signal held in the capacitor 1208 is retained for a long time also in a period during which the power supply voltage is not supplied to the memory element 1200. The memory element 1200 can accordingly retain the stored content (data) also in a period during which the supply of the power supply voltage is stopped.

Since the above-described memory element performs pre-charge operation with the switch 1203 and the switch 1204, the time required for the circuit 1201 to retain original data again after the supply of the power supply voltage is restarted can be shortened.

In the circuit 1202, a signal retained by the capacitor 1208 is input to the gate of the transistor 1210. Therefore, after supply of the power supply voltage to the memory element 1200 is restarted, the signal retained by the capacitor 1208 can be converted into the one corresponding to the state (the on state or the off state) of the transistor 1210 to be read from the circuit 1202. Consequently, an original signal can be accurately read even when a potential corresponding to the signal retained by the capacitor 1208 varies to some degree.

By applying the above-described memory element 1200 to a memory device such as a register or a cache memory included in a processor, data in the memory device can be prevented from being lost owing to the stop of the supply of the power supply voltage. Furthermore, shortly after the supply of the power supply voltage is restarted, the memory device can be returned to the same state as that before the power supply is stopped. Therefore, the power supply can be stopped even for a short time in the processor or one or a plurality of logic circuits included in the processor, resulting in lower power consumption.

Although the memory element 1200 is used in a CPU, the memory element 1200 can also be used in an LSI such as a digital signal processor (DSP), a custom LSI, or a programmable logic device (PLD), and a radio frequency identification (RF-ID).

### <Display Device>

The following shows configuration examples of a display device of one embodiment of the present invention.

### [Configuration Example]

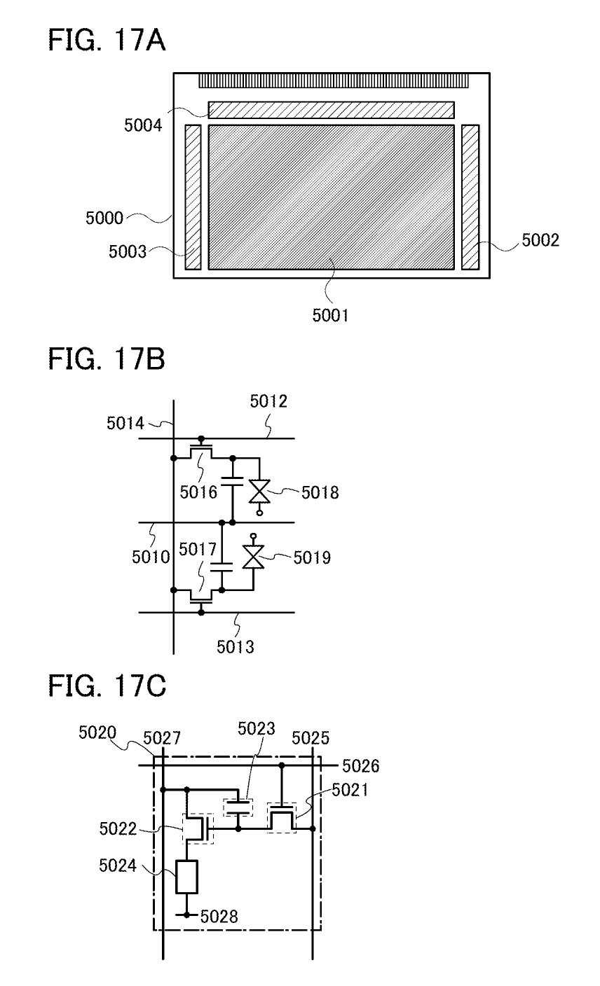

FIG. 17A is a top view of a display device of one embodiment of the present invention. FIG. 17B illustrates a pixel circuit where a liquid crystal element is used for a pixel of a display device of one embodiment of the present invention. FIG. 17C illustrates a pixel circuit where an organic EL element is used for a pixel of a display device of one embodiment of the present invention.

Any of the above-described transistors can be used as a transistor used for the pixel. Here, an example in which an n-channel transistor is used is shown. Note that a transistor manufactured through the same steps as the transistor used for the pixel may be used for a driver circuit. Thus, by using any of the above-described transistors for a pixel or a driver circuit, the display device can have high display quality and/or high reliability.

FIG. 17A illustrates an example of an active matrix display device. A pixel portion 5001, a first scan line driver circuit 5002, a second scan line driver circuit 5003, and a signal line driver circuit 5004 are provided over a substrate 5000 in the display device. The pixel portion 5001 is electrically connected to the signal line driver circuit 5004 through a plurality of signal lines and is electrically connected to the first scan line driver circuit 5002 and the second scan line driver circuit 5003 through a plurality of scan lines. Pixels including display elements are provided in respective regions divided by the scan lines and the signal lines. The substrate 5000 of the display device is electrically connected to a timing control circuit (also referred to as a controller or a control IC) through a connection portion such as a flexible printed circuit (FPC).

The first scan line driver circuit 5002, the second scan line driver circuit 5003, and the signal line driver circuit 5004 are formed over the substrate 5000 where the pixel portion 5001 is formed. Therefore, a display device can be manufactured at cost lower than that in the case where a driver circuit is separately formed. Furthermore, in the case where a driver circuit is separately formed, the number of wiring connections is increased. By providing the driver circuit over the substrate 5000, the number of wiring connections can be reduced. Accordingly, the reliability and/or yield can be improved.

### [Liquid Crystal Display Device]

FIG. 17B illustrates an example of a circuit configuration of the pixel. Here, a pixel circuit which is applicable to a pixel of a VA liquid crystal display device, or the like is illustrated.

This pixel circuit can be applied to a structure in which one pixel includes a plurality of pixel electrodes. The pixel electrodes are connected to different transistors, and the transistors can be driven with different gate signals. Accordingly, signals applied to individual pixel electrodes in a multi-domain pixel can be controlled independently.

A gate wiring 5012 of a transistor 5016 and a gate wiring 5013 of a transistor 5017 are separated so that different gate signals can be supplied thereto. In contrast, a source or drain electrode 5014 functioning as a data line is shared by the transistors 5016 and 5017. Any of the above-described transistors can be used as appropriate as each of the transistors 5016 and 5017. Thus, the liquid crystal display device can have a high display quality and/or high reliability.

A first pixel electrode is electrically connected to the transistor 5016 and a second pixel electrode is electrically connected to the transistor 5017. The first pixel electrode and the second pixel electrode are separated. Shapes of the first pixel electrode and the second pixel electrode are not especially limited. For example, the first pixel electrode may have a V-like shape.

A gate electrode of the transistor 5016 is electrically connected to the gate wiring 5012, and a gate electrode of the transistor 5017 is electrically connected to the gate wiring 5013. When different gate signals are supplied to the gate wiring 5012 and the gate wiring 5013, operation timings of the transistor 5016 and the transistor 5017 can be varied. As a result, alignment of liquid crystals can be controlled.

Furthermore, a capacitor may be formed using a capacitor wiring 5010, a gate insulator functioning as a dielectric, and a capacitor electrode electrically connected to the first pixel electrode or the second pixel electrode.

The multi-domain pixel includes a first liquid crystal element 5018 and a second liquid crystal element 5019 in one pixel. The first liquid crystal element 5018 includes the first pixel electrode, a counter electrode, and a liquid crystal layer therebetween. The second liquid crystal element 5019 includes the second pixel electrode, a counter electrode, and a liquid crystal layer therebetween.

Note that a pixel circuit in the display device of one embodiment of the present invention is not limited to that shown in FIG. 17B. For example, a switch, a resistor, a capacitor, a transistor, a sensor, a logic circuit, or the like may be added to the pixel circuit shown in FIG. 17B.

### [Organic EL Panel]

FIG. 17C illustrates another example of a circuit configuration of the pixel. Here, a pixel structure of a display device using an organic EL element is shown.

In an organic EL element, by application of voltage to a light-emitting element, electrons are injected from one of a pair of electrodes included in the organic EL element and holes are injected from the other of the pair of electrodes, into a layer containing a light-emitting organic compound; thus, current flows. The electrons and holes are recombined, and thus, the light-emitting organic compound is excited. The light-emitting organic compound returns to a ground state from the excited state, thereby emitting light. Owing to such a mechanism, this light-emitting element is referred to as a current-excitation light-emitting element.

FIG. 17C illustrates an example of a pixel circuit. Here, one pixel includes two n-channel transistors. Note that any of the above-described transistors can be used as the n-channel transistors. Furthermore, digital time grayscale driving can be employed for the pixel circuit.

The configuration of the applicable pixel circuit and operation of a pixel employing digital time grayscale driving will be described.

A pixel 5020 includes a switching transistor 5021, a driver transistor 5022, a light-emitting element 5024, and a capacitor 5023. A gate electrode of the switching transistor 5021 is connected to a scan line 5026, a first electrode (one of a source electrode and a drain electrode) of the switching transistor 5021 is connected to a signal line 5025, and a second electrode (the other of the source electrode and the drain electrode) of the switching transistor 5021 is connected to a gate electrode of the driver transistor 5022. The gate electrode of the driver transistor 5022 is connected to a power supply line 5027 through the capacitor 5023, a first electrode of the driver transistor 5022 is connected to the power supply line 5027, and a second electrode of the driver transistor 5022 is connected to a first electrode (a pixel electrode) of the light-emitting element 5024. A second electrode of the light-emitting element 5024 corresponds to a common electrode 5028. The common electrode 5028 is electrically connected to a common potential line provided over the same substrate.

As each of the switching transistor 5021 and the driver transistor 5022, any of the above-described transistors can be used as appropriate. In this manner, an organic EL display device having high display quality and/or high reliability can be provided.

The potential of the second electrode (the common electrode 5028) of the light-emitting element 5024 is set to be a low power supply potential. Note that the low power supply potential is lower than a high power supply potential supplied to the power supply line 5027. For example, the low power supply potential can be GND, 0 V, or the like. The high power supply potential and the low power supply potential are set to be higher than or equal to the forward threshold voltage of the light-emitting element 5024, and the difference between the potentials is applied to the light-emitting element 5024, whereby current is supplied to the light-emitting element 5024, leading to light emission. The forward voltage of the light-emitting element 5024 refers to a voltage at which a desired luminance is obtained, and includes at least forward threshold voltage.

Note that gate capacitance of the driver transistor 5022 may be used as a substitute for the capacitor 5023 in some cases, so that the capacitor 5023 can be omitted. The gate capacitance of the driver transistor 5022 may be formed between the channel formation region and the gate electrode.

Next, a signal input to the driver transistor 5022 is described. In the case of a voltage-input voltage driving method, a video signal for turning on or off the driver transistor 5022 is input to the driver transistor 5022. In order for the driver transistor 5022 to operate in a linear region, voltage higher than the voltage of the power supply line 5027 is applied to the gate electrode of the driver transistor 5022. Note that voltage higher than or equal to voltage which is the sum of power supply line voltage and the threshold voltage Vₜₕ of the driver transistor 5022 is applied to the signal line 5025.

In the case of performing analog grayscale driving, a voltage higher than or equal to a voltage which is the sum of the forward voltage of the light-emitting element 5024 and the threshold voltage Vₜₕ of the driver transistor 5022 is applied to the gate electrode of the driver transistor 5022. A video signal by which the driver transistor 5022 is operated in a saturation region is input, so that current is supplied to the light-emitting element 5024. In order for the driver transistor 5022 to operate in a saturation region, the potential of the power supply line 5027 is set higher than the gate potential of the driver transistor 5022. When an analog video signal is used, it is possible to supply current to the light-emitting element 5024 in accordance with the video signal and perform analog grayscale driving.

Note that in the display device of one embodiment of the present invention, a pixel configuration is not limited to that shown in FIG. 17C. For example, a switch, a resistor, a capacitor, a sensor, a transistor, a logic circuit, or the like may be added to the pixel circuit shown in FIG. 17C.

In the case where any of the above-described transistors is used for the circuit shown in FIGS. 17A to 17C, the source electrode (the first electrode) is electrically connected to the low potential side and the drain electrode (the second electrode) is electrically connected to the high potential side. Furthermore, the potential of the first gate electrode may be controlled by a control circuit or the like and the potential described above as an example, e.g., a potential lower than the potential applied to the source electrode, may be input to the second gate electrode.

### <Electronic Device>

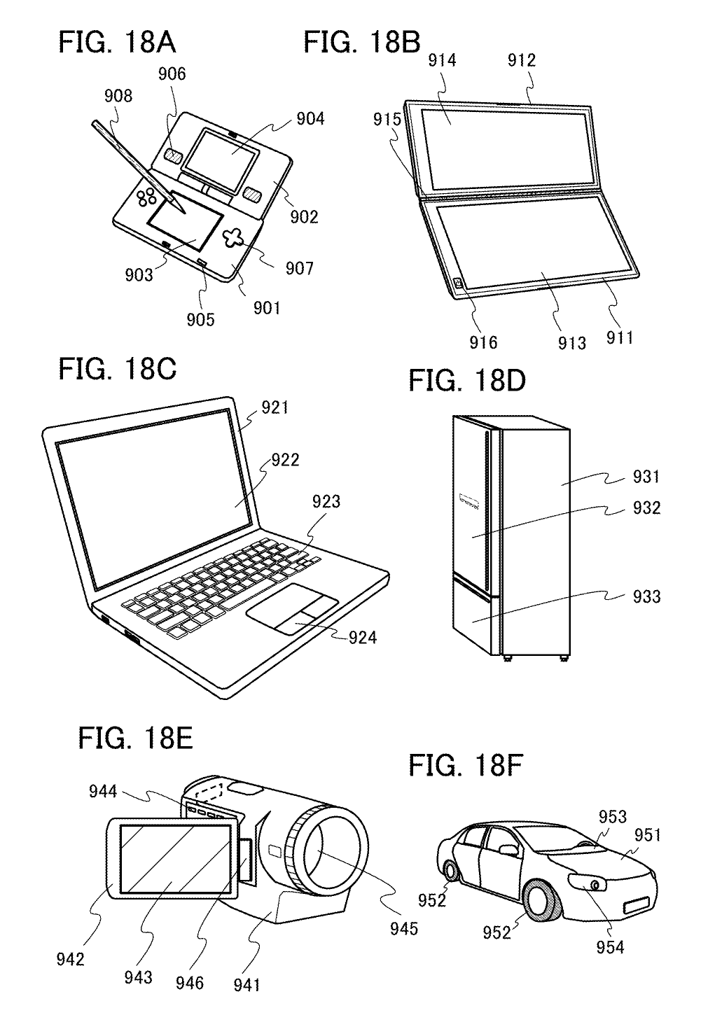

The semiconductor device of one embodiment of the present invention can be used for display devices, personal computers, or image reproducing devices provided with recording media (typically, devices which reproduce the content of recording media such as digital versatile discs (DVDs) and have displays for displaying the reproduced images). Other examples of electronic devices that can be equipped with the semiconductor device of one embodiment of the present invention are mobile phones, game machines including portable game consoles, portable data terminals, e-book readers, cameras such as video cameras and digital still cameras, goggle-type displays (head mounted displays), navigation systems, audio reproducing devices (e.g., car audio systems and digital audio players), copiers, facsimiles, printers, multifunction printers, automated teller machines (ATM), and vending machines. FIGS. 18A to 18F illustrate specific examples of these electronic devices.

FIG. 18A illustrates a portable game console including a housing 901, a housing 902, a display portion 903, a display portion 904, a microphone 905, a speaker 906, an operation key 907, a stylus 908, and the like. Although the portable game console in FIG. 18A has the two display portions 903 and 904, the number of display portions included in a portable game console is not limited to this.

FIG. 18B illustrates a portable data terminal including a first housing 911, a second housing 912, a first display portion 913, a second display portion 914, a joint 915, an operation key 916, and the like. The first display portion 913 is provided in the first housing 911, and the second display portion 914 is provided in the second housing 912. The first housing 911 and the second housing 912 are connected to each other with the joint 915, and the angle between the first housing 911 and the second housing 912 can be changed with the joint 915. An image on the first display portion 913 may be switched in accordance with the angle at the joint 915 between the first housing 911 and the second housing 912. A display device with a position input function may be used as at least one of the first display portion 913 and the second display portion 914. Note that the position input function can be added by providing a touch panel in a display device. Alternatively, the position input function can be added by providing a photoelectric conversion element called a photosensor in a pixel portion of a display device.

FIG. 18C illustrates a laptop personal computer, which includes a housing 921, a display portion 922, a keyboard 923, a pointing device 924, and the like.

FIG. 18D illustrates an electric refrigerator-freezer, which includes a housing 931, a door for a refrigerator 932, a door for a freezer 933, and the like.

FIG. 18E illustrates a video camera, which includes a first housing 941, a second housing 942, a display portion 943, operation keys 944, a lens 945, a joint 946, and the like. The operation keys 944 and the lens 945 are provided for the first housing 941, and the display portion 943 is provided for the second housing 942. The first housing 941 and the second housing 942 are connected to each other with the joint 946, and the angle between the first housing 941 and the second housing 942 can be changed with the joint 946. Images displayed on the display portion 943 may be switched in accordance with the angle at the joint 946 between the first housing 941 and the second housing 942.

FIG. 18F illustrates an ordinary vehicle including a car body 951, wheels 952, a dashboard 953, lights 954, and the like.

### Example 1

In this example, CAAC-IGZO, nc-IGZO, and a-like IGZO were measured by XRD.

As CAAC-IGZO, a 100-nm-thick In—Ga—Zn oxide was deposited over a quartz substrate by a sputtering method. As a target, an In—Ga—Zn oxide (In:Ga:Zn=1:1:1 [atomic ratio]) was used. As a deposition gas, 30 sccm of an oxygen gas was used. Power of 200 W (DC) was used. A substrate temperature at the time of the deposition was set to 300° C. The deposition pressure was set to 0.4 Pa.

As first nc-IGZO (1), a 100-nm-thick In—Ga—Zn oxide was deposited over a quartz substrate by a sputtering method. As a target, an In—Ga—Zn oxide (In:Ga:Zn=1:1:1 [atomic ratio]) was used. As a deposition gas, 30 sccm of an argon gas was used. Power of 200 W (DC) was used. A substrate temperature at the time of the deposition was set to a room temperature. The deposition pressure was set to 0.4 Pa.

As second nc-IGZO (2), a 100-nm-thick In—Ga—Zn oxide was deposited over a quartz substrate by a sputtering method. As a target, an In—Ga—Zn oxide (In:Ga:Zn=1:1:1 [atomic ratio]) was used. As a deposition gas, 20 sccm of an argon gas and 10 sccm of an oxygen gas were used. Power of 200 W (DC) was used. A substrate temperature at the time of the deposition was set to a room temperature. The deposition pressure was set to 0.4 Pa.

As third nc-IGZO (3), a 100-nm-thick In—Ga—Zn oxide was deposited over a quartz substrate by a sputtering method. As a target, an In—Ga—Zn oxide (In:Ga:Zn=1:1:1 [atomic ratio]) was used. As a deposition gas, 20 sccm of an argon gas and 10 sccm of an oxygen gas were used. Power of 200 W (RF) was used. A substrate temperature at the time of the deposition was set to a room temperature. The deposition pressure was set to 0.4 Pa.

As first a-like IGZO (1), a 100-nm-thick In—Ga—Zn oxide was deposited over a quartz substrate by a sputtering method. As a target, an In—Ga—Zn oxide (In:Ga:Zn=1:1:1 [atomic ratio]) was used. As a deposition gas, 30 sccm of an argon gas was used. Power of 50 W (DC) was used. A substrate temperature at the time of the deposition was set to a room temperature. The deposition pressure was set to 1.0 Pa.

As second a-like IGZO (2), a 100-nm-thick In—Ga—Zn oxide was deposited over a quartz substrate by a sputtering method. As a target, an In—Ga—Zn oxide (In:Ga:Zn=1:1:1 [atomic ratio]) was used. As a deposition gas, 20 sccm of an argon gas and 10 sccm of an oxygen gas were used. Power of 50 W (DC) was used. A substrate temperature at the time of the deposition was set to a room temperature. The deposition pressure was set to 1.0 Pa.

As third a-like IGZO (3), a 100-nm-thick In—Ga—Zn oxide was deposited over a quartz substrate by a sputtering method. As a target, an In—Ga—Zn oxide (In:Ga:Zn=1:1:1 [atomic ratio]) was used. As a deposition gas, 20 sccm of an argon gas and 10 sccm of an oxygen gas were used. Power of 100 W (DC) was used. A substrate temperature at the time of the deposition was set to a room temperature. The deposition pressure was set to 1.0 Pa.

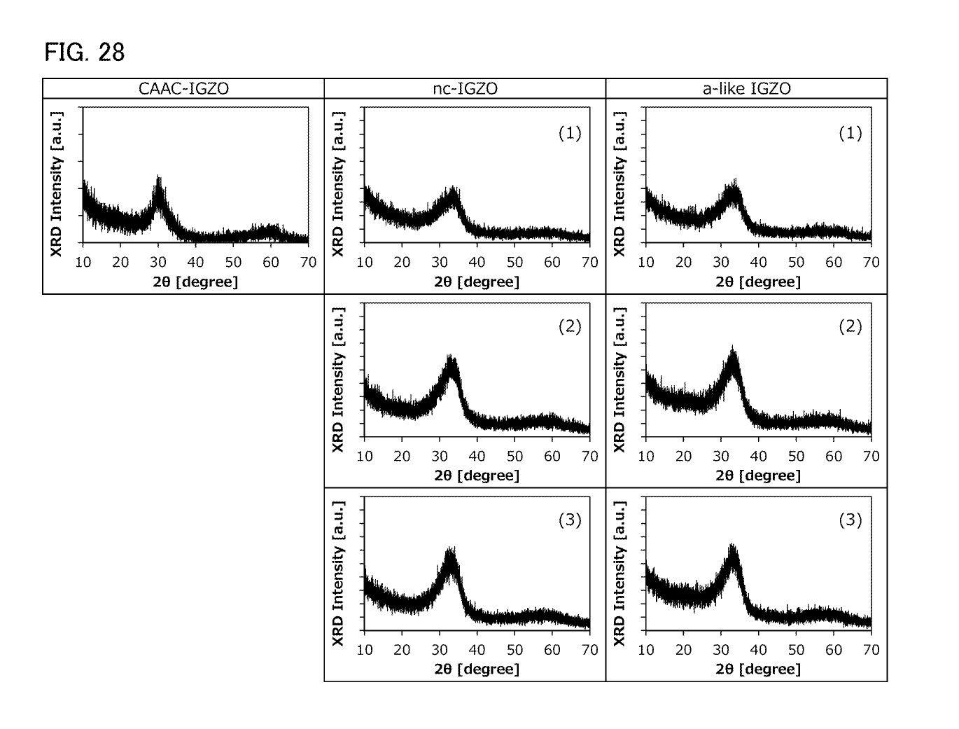

Next, each sample was measured by XRD. A thin film method was used for the XRD measurement. FIG. 28 shows the measurement result.

As shown in FIG. 28, a peak at 2θ of around 31° that shows crystallinity was observed. Furthermore, in the nc-IGZO and the a-like IGZO, the interference derived from a near neighbor atom was observed at 2θ of, for example, around 33°.

Also in this example, the nc-IGZO and the a-like IGZO cannot be distinguished from each other by XRD.

This application is based on Japanese Patent Application serial no. 2014-099578 filed with Japan Patent Office on May 13, 2014, Japanese Patent Application serial no. 2014-126080 filed with Japan Patent Office on Jun. 19, 2014, and Japanese Patent Application serial no. 2014-206219 filed with Japan Patent Office on Oct. 7, 2014, the entire contents of which are hereby incorporated by reference.

What is claimed is:

1. An oxide comprising:
indium;
an element M, the element M being aluminum, gallium, yttrium, or tin; and
zinc,
wherein the oxide comprises a first region,
wherein in the first region a peak of diffraction intensity derived from a crystal structure is not observed using X-ray,
wherein the oxide comprises a second region,
wherein an electron diffraction pattern including a third region with high luminance in a ring pattern and a spot in the third region is observed by transmission of an electron beam having a probe diameter of 0.3 nm or more and 3 nm or less through the second region,
wherein the oxide includes a crystal part when being observed with a transmission electron microscope,
wherein the crystal part has a first length in a longitudinal direction, and
wherein change in the first length is less than 10% when the oxide is subjected to electron irradiation and the total amount of the electron irradiation is 1×10⁸ e⁻/nm² or more and 4×10⁸ e⁻/nm² or less.

2. A semiconductor device comprising:
a semiconductor including the oxide according to claim 1;
an insulator; and
a conductor,
wherein the insulator includes a region in contact with the semiconductor, and
wherein the conductor includes a region where the conductor and the semiconductor overlap with each other with the insulator therebetween.

3. A module comprising:
the semiconductor device according to claim 2; and
a printed board.

4. An electronic device comprising:
the semiconductor device according to claim 2 or the module according to claim 3; and
a speaker, an operation key, or a battery.
